(19) United States
(12) Patent Application Publication
(10) Pub. No.: US 2025/0204208 A1
(43) Pub. Date: Jun. 19, 2025

(54) DISPLAY DEVICE

(71) Applicant: LG DISPLAY CO., LTD., Seoul (KR)

(72) Inventor: Jae Ho JUNG, Paju-si (KR)

(73) Assignee: LG DISPLAY CO., LTD., Seoul (KR)

(21) Appl. No.: 18/674,524

(22) Filed: May 24, 2024

(30) Foreign Application Priority Data
Dec. 18, 2023 (KR) 10-2023-0184645

(51) Int. Cl. H10K 59/80

(52) U.S. Cl. CPC H10K 59/871

(57) ABSTRACT

A display device includes a display panel, a plate arranged on a back surface of the display panel, a substrate and a support member, both arranged on a back surface of the plate, and a flexible film connecting the display panel and the substrate to each other, wherein the flexible film is attached to a back surface of the support member by a first adhesive member.

### CROSS-REFERENCE TO RELATED APPLICATION

This application claims priority to and the benefit of Korean Patent Application No. 10-2023-0184645, filed Dec. 18, 2023, the disclosure of which is incorporated herein by reference in its entirety.

### BACKGROUND

### Technical Field

The embodiments of the present disclosure relate to a display device.

### Discussion of the Related Art

Electroluminescent display devices include organic light-emitting display devices, in which organic light-emitting diodes (OLED) are arranged, and inorganic light-emitting displays devices, in which inorganic light-emitting diodes (LED) are arranged.

The electroluminescent display device displays an image using self-light-emitting elements, and thus may be realized in various thin shapes without requiring a separate light source, for example, a backlight unit.

The organic light-emitting display device activates organic light-emitting diodes (OLED), arranged on pixels, respectively, according to an input image signal, thereby reproducing an image. The organic light-emitting display device has fast pixel response time, high light-emitting efficiency, high luminance, and a wide viewing angle. Moreover, the organic light-emitting display device can express complete black in terms of black grayscale, thereby realizing an excellent contrast ratio and color reproduction ratio.

The inorganic light-emitting display device activates inorganic light-emitting diodes (LED), arranged on pixels, respectively, according to an input image signal, thereby reproducing an image. The inorganic light-emitting diode is made of an inorganic material, thereby having high moisture (for example, water) resistance and thus having excellent reliability compared to the organic light-emitting diode. In addition, the inorganic light-emitting diode has fast turning-on time, high light-emitting efficiency, and excellent impact resistance.

A flexible film electrically connecting a display panel and a circuit substrate to each other needs a predetermined space for a bending section thereof. However, the predetermined space imposes a limitation on the realization of a compact display device. For example, due to the material and structure of the flexible film, the flexible film includes the bending section and the bending section protrudes outward, thereby imposing a limitation on the realization of a narrow bezel of a display device. The flexible film here may be formed of a ductile material in a thin manner.

### SUMMARY

Accordingly, embodiments of the present disclosure are directed to a display device that substantially obviates one or more of the problems due to limitations and disadvantages of the related art.

An aspect of the present disclosure is to provide a display device capable of adjusting the extent to which a bending section of a flexible film protrudes, using a support member and an adhesive member, thereby reducing the size of a bezel of the display device.

Another aspect of the present disclosure is to provide a display device capable of preventing shaking and the like of a flexible film, using a support member and an adhesive member, thereby preventing or minimizing the likelihood of a potential defect occurring in respective connecting portions of a display panel of the display device and the flexible film.

Another aspect of the present disclosure is to provide a display device capable of including a sharable support member that may be used in a case where the display device is of a flat type or a curved type, thereby improving the productivity of the display device.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises: a display panel; a plate arranged on a back surface of the display panel; a substrate and a support member, both arranged on a back surface of the plate; and a flexible film connecting the display panel and the substrate to each other, wherein the flexible film is attached to a back surface of the support member by a first adhesive member.

In another aspect, a display device comprises: a display panel; a plate arranged on a back surface of the display panel; a substrate and a support member, both arranged on a back surface of the plate; a flexible film connecting the display panel and the substrate to each other; and a cover member arranged on a front surface side of the display panel, wherein the flexible film is attached to a back surface of the support member by a first adhesive member, wherein the cover member includes a curved surface with a predetermined curvature, and wherein the support member includes a plurality of grooves that are formed to be elongated in a first direction in such a manner as to be spaced apart from each other in a second direction that is different from the first direction.

According to an embodiment of the present disclosure, the size of the bezel of the display device may be reduced by adjusting the extent to which the bending section of the flexible film protrudes, using the support member and the adhesive member, thereby making the display device compact.

According to the embodiment of the present disclosure, the display device may keep the flexible film from being shaken or the like, using the support member and the adhesive member, thereby preventing or minimizing the potential likelihood of a defect occurring in respective connecting portions of the display panel of the display device and the flexible film. Accordingly, according to the embodiment of the present disclosure, the display device may lengthen the lifetime of the display panel, thereby enabling low-power driving in a production process in terms of reducing production energy consumption.

According to the embodiment of the present disclosure, the display device may include a sharable support member (for example, formed of a synthetic resin material) that may be used in a case where the display device is of a flat type or a curved type, thereby improving the productivity of the display device.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a perspective view illustrating a display device according to an embodiment of the present disclosure;

FIG. 2 is an exploded perspective view illustrating the display device according to an embodiment of the present disclosure;

FIG. 3 is a cross-sectional view taken along line I-I′ of FIG. 1;

FIG. 4 is an enlarged view illustrating a portion A of FIG. 3;

FIG. 5 is a block diagram schematically illustrating a configuration of a display device according to an embodiment of the present disclosure;

FIG. 6 is a cross-sectional view schematically illustrating a cross-sectional structure of a display area of a display device according to an embodiment of the present disclosure;

FIG. 7 is a perspective view illustrating a support member, as a first example, that is arranged in the display device according to an embodiment of the present disclosure;

FIG. 8 is a plan view illustrating the support member of the first example that is arranged in the display device according to an embodiment of the present disclosure;

FIG. 9 is a side view illustrating the support member of the first example that is arranged in the display device according to an embodiment of the present disclosure;

FIG. 10 is an enlarged view illustrating a support portion of the support member that is arranged in the display device according to an embodiment of the present disclosure;

FIG. 11 is a view illustrating an arrangement relationship between the support portion of the support member and a flexible film that is arranged in the display device according to an embodiment of the present disclosure;

FIG. 12 is a view schematically illustrating an arrangement relationship among a cover member, a display panel, a plate, and a support member, which are formed with a predetermined curvature in the display device according to an embodiment of the present disclosure;

FIG. 13 is a plan view illustrating an arrangement relationship between the support member and a first adhesive member in the display device according to an embodiment of the present disclosure;

FIG. 14 is a side view illustrating an arrangement relationship between the support member and the first adhesive member of the display device according to an embodiment of the present disclosure;

FIG. 15 is a view illustrating a filling member of the display device according to an embodiment of the present disclosure;

FIG. 16 is a view illustrating grooves in a support member, as a second example, which is arranged on the display device according to an embodiment of the present disclosure;

FIG. 17 is a plan view illustrating a support member, as a third example, which is arranged in the display device according to an embodiment of the present disclosure;

FIG. 18 is a side view illustrating the support member of the third example, which is arranged in the display device according to an embodiment of the present disclosure;

FIG. 19 is a view illustrating an arrangement relationship among the cover member, the display panel, and the plate, and the support member of the third example, which are formed with a predetermined curvature of the display device according to an embodiment of the present disclosure;

FIG. 20 is a plan view illustrating a support member, as a fourth example (in other words, fourth practical example), which is arranged in the display device according to an embodiment of the present disclosure;

FIG. 21 is a side view illustrating the support member of the fourth example, which is arranged in the display device according to the embodiment of the present disclosure;

FIG. 22 is a view illustrating an arrangement relationship among the cover member, the display panel, the plate, and the support member of the fourth example, which are formed with a predetermined curvature of the display device according to the embodiment of the present disclosure; and

FIG. 23 is a view illustrating an example where the display device according to an embodiment of the present disclosure is used, that is, an example where the display device is installed in a vehicle.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the embodiments will make the disclosure of the present disclosure complete and allow those skilled in the art to completely comprehend the scope of the present disclosure. The present disclosure is only defined by the scope of the accompanying claims.

In describing the present disclosure, detailed descriptions of known related technologies may be omitted so as not to unnecessarily obscure the subject matter of the present disclosure.

The terms such as “comprising”, “including”, “having” and “consisting of” used herein are generally intended to allow other components to be added unless the terms are used with the term “only”. References to the singular shall be construed to include the plural unless expressly stated otherwise.

When describing a positional or interconnected relationship between two components, such as “on top of”, “above”, “below”, “next to”, “connect or couple with”, “crossing”, “intersecting” etc., one or more other components may be interposed between them unless “immediately” or “directly” is used.

When describing a temporal contextual relationship, such as “after”, “following”, “next to” or “before”, it may not be continuous on a time scale unless “immediately” or “directly” is used.

The terms “first”, “second” and the like may be used to distinguish components from each other, but the functions or structures of the components are not limited by ordinal numbers or component names in front of the components.

The following embodiments may be combined or associated with each other in whole or in part, and various types of interlocking and driving are technically possible. The embodiments may be implemented independently of each other or together in an interrelated relationship.

Terms used in the embodiments of the disclosure (including technical and scientific terms) are to be construed as they would be commonly understood by one of ordinary skill in the art to which the invention belongs, unless otherwise specifically defined and described, and commonly used terms, such as dictionary defined terms, are to be construed in light of their contextual meaning in the relevant art.

Hereinafter, preferred embodiments of the present disclosure will be described in detail with reference to the accompanying drawings.

In the recent information society, display devices have become increasingly important as visual information transmission media, and they are being improved to meet requirements such as low power consumption, thinness, weight reduction, high definition, and high efficiency.

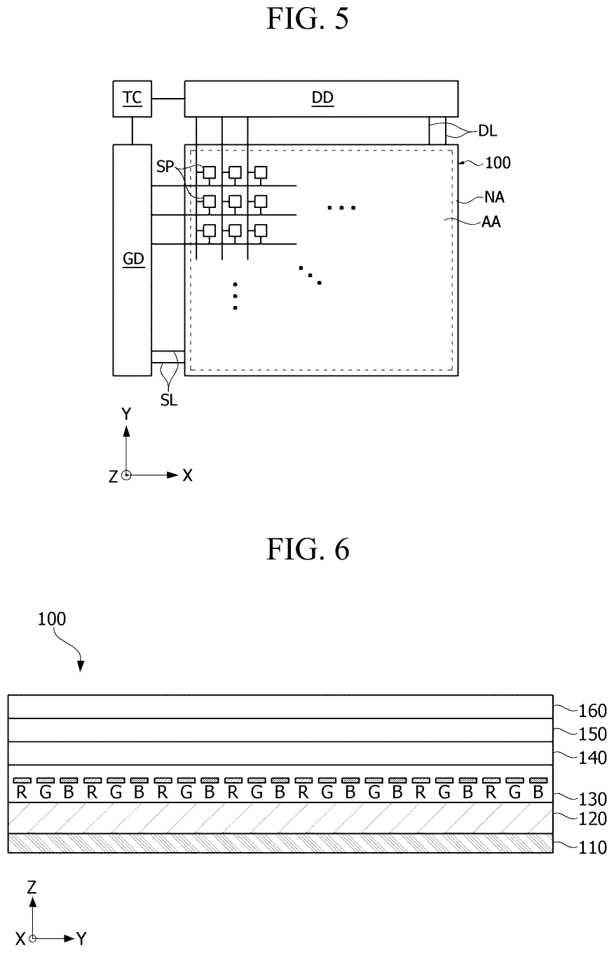

In a display device according to an embodiment of the present disclosure, an area that is occupied by a bezel, which is a non-display area NA (for example, see FIG. 5), may be reduced by decreasing a space occupied by a flexible film using a support member and an adhesive member. That is, the display device 1 according to the embodiment of the present disclosure, in which a narrow bezel is realized, may be provided as a compact display device.

In the display device according to the embodiment of the present disclosure, the flexible film is fixed and supported using the support member and the adhesive member. Thus, damage to the flexible film or separation of a connecting portion of the flexible film, which is caused by a predetermined load applied to the flexible film, may be prevented. Accordingly, an improvement in the durability of the display device 1 according to the embodiment of the present disclosure lengthens the lifespan thereof, making it possible to reduce greenhouse gas emissions in terms of reducing production energy consumption.

The display device according to the embodiment of the present disclosure may provide the support member which is usable in a case where the display device is of a flat-type or a curved-type, thereby improving the productivity of the display device.

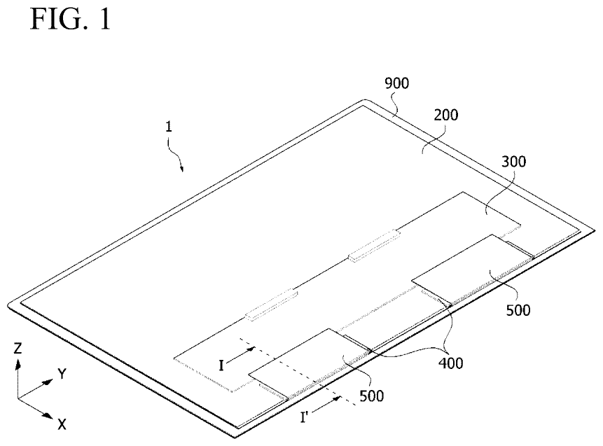

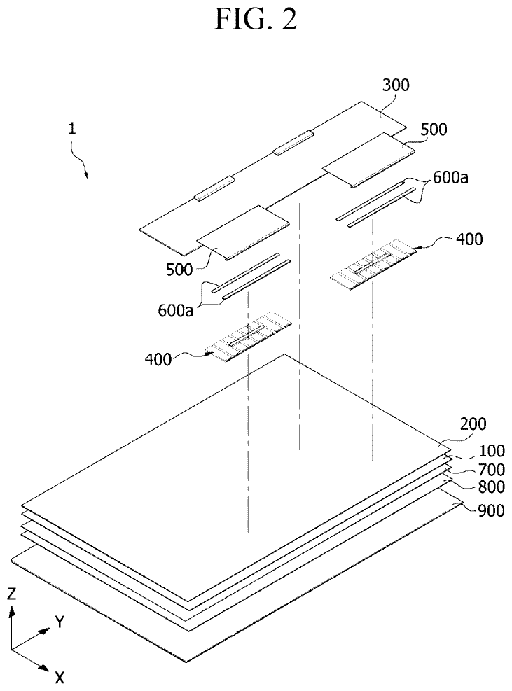

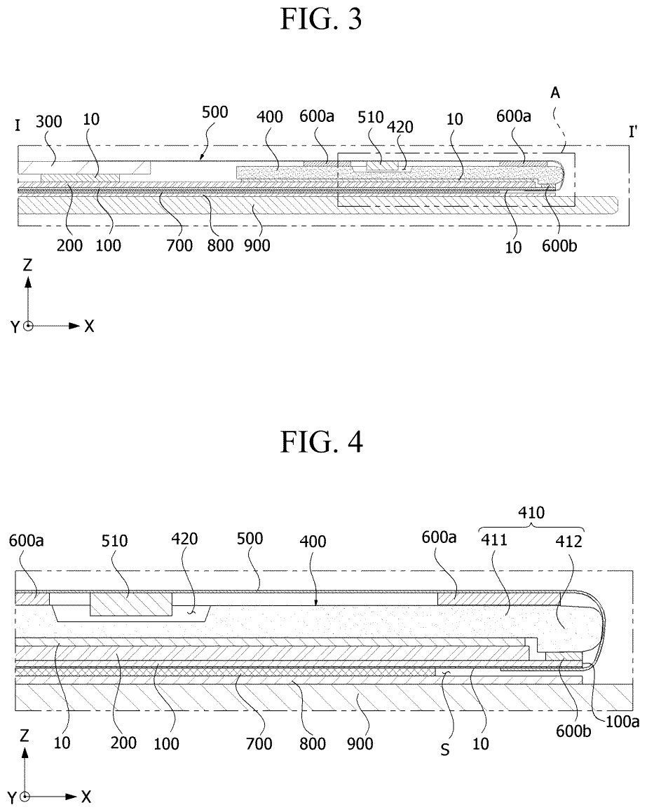

FIG. 1 is a perspective view illustrating the display device 1 according to the embodiment of the present disclosure. FIG. 2 is an exploded perspective view illustrating the display device 1 according to the embodiment of the present disclosure. FIG. 3 is a cross-sectional view taken along line I-I′ of FIG. 1. FIG. 4 is an enlarged view illustrating a portion A of FIG. 3.

With reference to FIGS. 1 to 4, the display device 1 according to the embodiment of the present disclosure may include: a display panel 100; a plate 200 arranged on a back surface of the display panel 100; a substrate 300 and a support member 400, both being arranged on a back surface of the plate 200; a flexible film 500 connecting the display panel 100 and the substrate 300 to each other; and a first adhesive member 600a attaching one region of the flexible film 500 to a back surface of the support member 400. In this case, the flexible film 500 may include a bending section that occurs when the flexible film 500 is bent. However, fixing one side of the flexible film 500 to the support member 400 through the first adhesive member 600a may minimize protrusion of the bending section toward the outside. A term “inside” here may be defined as indicating a direction toward the center of the display panel 100, and the term “outside” may be defined as indicating the direction opposite to the “inside”. One surface, on which an input image is displayed, of the display panel 100 may be referred to as a front surface of the display panel 100, and a surface opposite to the front surface may be referred to as a back surface. In this case, the X-axis direction illustrated in FIGS. 1 to 3 may refer to a widthwise or transverse direction, the Y-axis direction may refer to a lengthwise or longitudinal direction, and the Z-axis direction may refer to a thickness or upward-downward direction. In addition, the X-axis direction, the Y-axis direction, and the Z-axis direction may be perpendicular to each other, but may also refer to different directions, respectively, that are not perpendicular to each other. Accordingly, each of the X-axis, Y-axis, and Y-axis directions may be expressed as any one of first, second, and third directions. Then, a surface extending in the X-axis direction and the Y-axis direction may refer to a horizontal surface.

In addition, the display device 1 according to the embodiment of the present disclosure may further include: an optical member 700 arranged on the front surface of the display panel 100; a cover adhesive member 800 arranged on a front surface of the optical member 700; and a cover member 900 arranged on a front surface side of the display panel 100, wherein the cover adhesive member 800 is located between the optical member 700 and the cover member 900.

In addition, the display device 1 according to the embodiment of the present disclosure may further include a housing in order to protect the display panel 100, the plate 200, the substrate 300, the support member 400, the flexible film 500, and the like.

The housing, along with the cover member 900, may constitute an exterior contour of the display device 1 according to the embodiment of the present disclosure. In this case, the housing may widely vary in shape due to the display panel 100, the plate 200, the substrate 300, the support member 400, the flexible film 500 and the like, all of which are arranged within the housing. In the display device 1 according to the embodiment of the present disclosure, the extent to which the bending section protrudes due to the bending of the flexible film 500 may be adjusted through the support member 400 and the first adhesive member 600a, thereby providing a slim-sized housing.

The housing may be formed in a cylindrical shape that is open at one side. In this case, the housing may widely vary in shape or material. For example, the housing may be formed of a synthetic resin material for use in forming various shapes, but is not necessarily limited to this material. The housing may also be formed of a metal material, such as aluminum highly resistant to high temperatures.

In addition, coupling the cover member 900, arranged on an opening side of the housing, to the housing may form an accommodation space within the housing. Accordingly, the display panel 100, the plate 200, the substrate 300, the support member 400, the flexible film 500, and the like may be arranged within the accommodation space.

The display panel 100 is arranged on the opening side of the housing, and an input image may be displayed on the display panel 100. The display panel 100 may be formed in the shape of a plate with a predetermined thickness and may have a front surface, on which an image is displayed, and a back surface opposite to the front surface. Here, the back surface may be one surface of the display panel 100 arranged on the upper portion, in the Z-axis direction, of the drawings (see FIG. 3).

In addition, the flexible film 500 may be electrically connected to a pad portion of the display panel 100. For example, the flexible film 500 may be bonded to the pad portion of the display panel 100 through an anisotropic conductive film (ACF).

FIG. 5 is a block diagram schematically illustrating a configuration of the display device 1 according to the embodiment of the present disclosure.

With reference to FIG. 5, the display device 1 includes a display panel 100 in which a plurality of pixels are arranged in a display area AA and a driving circuit for driving the pixels.

The display panel 100 may be a panel having a rectangular structure with a width in the X-axis direction, a length in the Y-axis direction, and a thickness in the Z-axis direction. The pixels each have a plurality of sub-pixels SP that may emit light of different colors. The driving circuit may include a data driver DD, a gate driver GD, and a timing controller TC controlling the gate driver GD and the data driver DD. The display area AA, on which an input image is displayed, of the display panel 100 may be a screen visible when viewed from above the front surface of the display panel 100. In this case, the width and length of the display panel 100 may be set to various design values that vary among application fields of the display device 1.

An input image is displayed on the sub-pixels SPs that are arranged on the display area AA of the display panel 100. The sub-pixels SPs each include a light-emitting element and a pixel circuit that drives the light-emitting element. The light-emitting element may be a light-emitting diode (LED) or a micro-light-emitting diode (micro-LED).

A plurality of scan lines SL and a plurality of data lines DL are arranged in an intersecting manner on the display panel 100. The sub-pixels SP each are connected to the scan line SL and the data line DL. Power lines, omitted from FIG. 5, may be connected to the sub-pixels SP, respectively. A non-display area NA may be arranged outward from the display area AA of the display panel 100.

The gate driver GD supplies a scan signal to the scan lines SL in response to a gate control signal provided from the timing controller TC. The gate driver GD, as illustrated in FIG. 5, may be arranged in at least the non-display area NA of the display panel 100 or within the display area AA.

In response to a data control signal provided from the timing controller TC, the data driver DD converts image data, received from the timing controller TC, into a reference compensation voltage, and outputs a data voltage. The data voltage, output from the data driver DD, is supplied to the data lines DL.

The timing controller TC aligns image data, input from the outside, and supplies the aligned image data to the data driver DD. The timing controller TC may generate the gate control signal and the data control signal based on timing signals, synchronized to an input image signal, for example, based on a dot clock signal, a data enable signal, and a horizontal/vertical synchronization signal. The timing controller TC supplies the gate control signal to the gate driver GD, supplies the data control signal to the data driver DD, and thus controls operational timing of both the gate driver GD and the data driver DD.

A link line and a pad electrode, both for transferring a signal to the sub-pixel SP in the display area AA, may be arranged in the non-display area NA. In addition, one or both of gate and data driver ICs may be arranged in the non-display area NA. The gate driver IC is formed by integrating circuits of the gate driver GD, and the data driver IC is formed by integrating circuits of the data driver DD. The non-display area NA may be positioned on the back surface of the display panel 100, that is, on the back surface on which the sub-pixel SP is not present, or may be minimized in size to the extent to which an image is invisible when displayed on the display panel 100.

Drivers, such as the gate driver GD, the data driver DD, and the timing controller TC, may be connected to the display panel 100 in various techniques. For example, the gate driver GD may also be arranged in the non-display area NA in a gate-in-panel (GIP) technique, and may also be arranged between the sub-pixels SPs in the display area AA in a gate-in-active-area (GIA) technique. For example, the data driver DD and the timing controller TC are formed on a separate flexible film and a separate printed circuit board (PCB), respectively. Then, the flexible film and the PCB are bonded to a pad electrode formed in the non-display area NA of the display panel 100. Thus, the data driver DD and the timing controller TC may be electrically connected to the display panel 100.

FIG. 6 is a cross-sectional view schematically illustrating a cross-sectional structure of the display area AA of the display device 1 according to the embodiment of the present disclosure.

With reference to FIG. 6, the display panel 100 may include a circuit layer 120, arranged on a panel substrate 110, and a light-emitting element layer 130, arranged on the circuit layer 120. In addition, the display panel 100 may include an encapsulation layer 140, arranged on the light-emitting element layer 130, a touch sensor layer 150, formed on the encapsulation layer 140, and a color filter layer 160, arranged on the touch sensor layer 150.

The panel substrate 110 may be formed of an insulation material or of a material with flexibility properties. For example, the panel substrate 110 may be formed of glass, metal, plastic, or the like.

The circuit layer 120 may include a pixel circuit, connected to wires such as data lines, gate lines, and electric power lines, a gate driver, connected to the gate lines, and the like. Wires and circuit elements on the circuit layer 120 may include a plurality of insulation layers, two or more metal layers, separated from each other with the insulation layer in between, and an active layer containing a semiconductor material.

The light-emitting element layer 130 may include a light-emitting element that is driven by the pixel circuit. The light-emitting element may include a red-color light-emitting element, a green-color light-emitting element, and a blue-color light-emitting element. In another practical example, the light-emitting element layer 130 may include a white-color light-emitting element and a color filter. Light-emitting elements on the light-emitting element layer 130 may be covered by a protective layer including an organic film and a protective film.

The encapsulation layer 140 covers the light-emitting element layer 130 in such a manner as to hermetically seal the circuit layer 120 and the light-emitting element layer 130. For example, the encapsulation layer 140 may have a multi-insulation film structure in which an organic film and an inorganic film are alternately stacked on top of each other. The inorganic film here blocks penetration of moisture or oxygen. The organic film flattens a surface of the inorganic film. When an organic film and an inorganic film are alternately stacked on top of each other, thereby forming several layers, a path for moisture or oxygen to move is lengthened compared to a single layer. This lengthening may effectively block penetration of moisture or oxygen affecting the light-emitting element layer 130.

The touch sensor layer 150 may include capacitive touch sensors that sense touch input based on changes in capacitance before and after the touch input. The touch sensor layer 150 may include metal line patterns and insulation films that form capacitances of touch sensors. The insulation films may insulate intersecting portions of the metal line patterns and may flatten a surface of the touch sensor layer 150.

A polarizer, omitted from the drawings, may be adhered on the touch sensor layer 150. The polarizer may improve visibility and contrast ratio by converting the polarization of external light, reflected by the metal line patterns on the circuit layer 120. The polarizer may be realized as a linear polarizer or as a circular polarizer that results from joining a linear polarizer and a phase retardation film to each other. The cover member 900 may be adhered on the polarizer. The cover member 900 here may be a cover glass formed of a glass material. The color filter layer 160 may be formed on the touch sensor layer 150.

The color filter layer 160 may include red, green, and blue color filters. In addition, the color filter layer 160 may further include a black matrix pattern. The color filter layer 160 may serve to substitute for the polarizer and may increase color purity by absorbing one portion of a wavelength of light reflected from the circuit layer 120. In this practical example, the color filter layer 160, which has a higher light transmittance than the polarizer, is used in the display panel 100. This use of the color filter layer 160 may improve the light transmittance of the display panel 100 and may improve or enhance the thickness and flexibility of the display panel 100. The cover member 900 may be adhered on the color filter layer 160.

The color filter layer 160 may include an organic film covering a color filter and a black matrix pattern. An extension portion of this organic film may cover a leftover portion of an inorganic film or the panel substrate 110 at a bezel area of the display panel 100, that is, at an edge area thereof.

The plate 200 may be formed to have a predetermined thickness and may be formed in a shape that corresponds to the back surface of the display panel 100. The plate 200 may be arranged between the display panel 100 and the substrate 300.

The plate 200 may support and protect the display panel 100 by being attached to the back surface of the display panel 100. For example, the fixation of the plate 200 to the back surface of the display panel 100 through an adhesive member may protect one side of the display panel 100 while supporting the display panel 100. The adhesive member here may be formed of an adhesive material, such as a form tape, and may be arranged along an edge of the plate 200.

The plate 200 may be manufactured from a material having rigid properties and high thermal conductivity, for example, from a metal material, such as aluminum (Al), a copper (Cu), zinc (Zn), silver (Ag), gold (Au), iron (Fe), stainless steel (STS), or invar. Accordingly, a uniform temperature distribution across the display panel 100 may be achieved by dispersing heat generated within the display panel 100 while minimizing variation of temperature among areas of the display panel 100.

In addition, a coating layer may be formed on the plate 200 in a manner that protects against damage or the like due to corrosion, a chemical material, or the like. For example, the coating layer may be formed on only one surface of the plate 200, taking into consideration exterior aesthetics, productivity, heat dissipation performance, and the like of the plate 200.

The coating layer on the plate 200 may be formed of an insulation material through a process of electric-deposition coating, but is not necessarily limited thereto. The electric-deposition coating here is one of coating methods in which a coating target serving as a positive or negative electrode is immersed in a solution containing water-soluble paint for electric deposition and in which a film of paint is electrically deposited on a surface of the coating target by causing direct current to flow between the coating target and an opposite electrode.

In addition, the coating layer may be provided in black color according to the blackbody heat radiation principle. Accordingly, a radiation ratio of the coating layer may reach or exceed 80%. The blackbody here refers to an object that completely absorbs even radiation in a range of all wavelengths, i.e., an object that absorbs all radiant energy incident from the outside and has a maximum radiation (absorption) ratio of 1 without any surface reflection, that is, with only re-radiation possible. The heat radiation emitted from the blackbody is referred to as blackbody radiation. In practice, it is difficult to manufacture a perfect blackbody having a radiation efficiency of 1, but it is feasible to increase radiation efficiency in a manner that is close to that of a blackbody. For example, charcoal or soot is close in radiation efficiency to the blackbody.

Therefore, a black-colored coating layer formed by the electric-deposition coating may increase the solidity of the film of paint and may improve the thermal transfer properties and heat radiation ratio of the plate 200. In addition, the plate 200 may block or minimize local transfer of heat generated in the substrate 300 to the display panel 100 by being arranged between the display panel 100 and the substrate 300.

The substrate 300 may be arranged on the back surface of the plate 200. In this case, the substrate 300 and the support member 400 may be arranged on the back surface of the plate 200 in such a manner as to be spaced apart from each other. The substrate 300 and the support member 400 may be attached to the back surface of the plate 200 using an adhesive member 10.

The substrate 300 may include a circuit substrate body in the shape of a plate and circuit elements mounted on the circuit substrate body. For example, the substrate 300 may include a camera, a main control module for a vehicle, a device for communication, a device for driving the display panel 100, and the like. In addition, the substrate 300 may include an internal circuit and various types of active elements and passive elements. The flexible film 500 may be electrically connected to one side of the circuit substrate body. The substrate 300 here may be a printed circuit board (PCB).

The support member 400 may be arranged on the back surface of the plate 200. In this case, the support member 400 may be arranged on an edge of the plate 200 in order to support the flexible film 500 that is bent. The support member 400 may be arranged in a manner that protrudes more outward than a lateral surface 100a of the display panel 100, taking into consideration a stress being applied to respective jointing portions of the display panel 100 and the flexible film 500. The support member 400 here may be formed of a synthetic resin material, such as plastic, taking into consideration the machinability thereof. For example, the support member 400 may be formed of a synthetic resin material having predetermined rigid properties, such as polycarbonate (PC), polyimide (PI), polyethylene naphthalate (PEN), polyethylene terephthalate (PET), or the like, but is not limited to these materials.

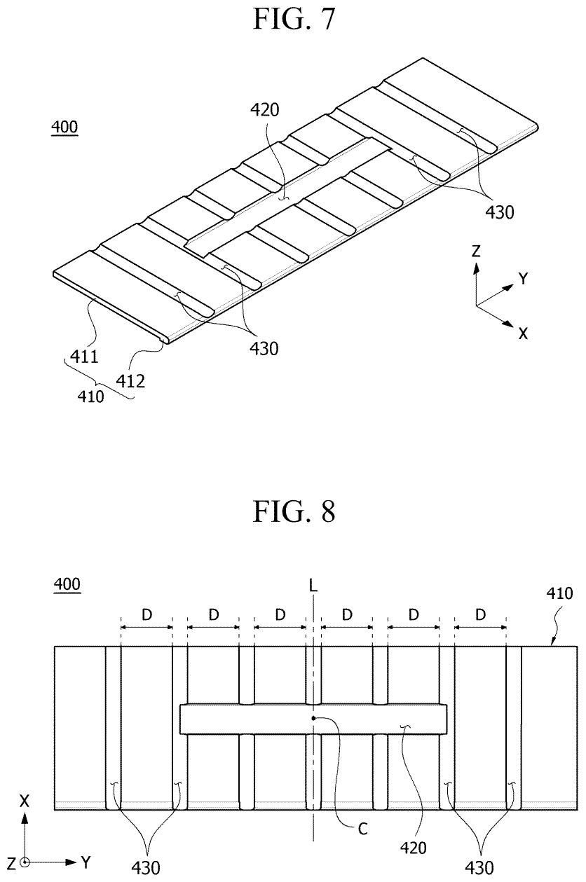

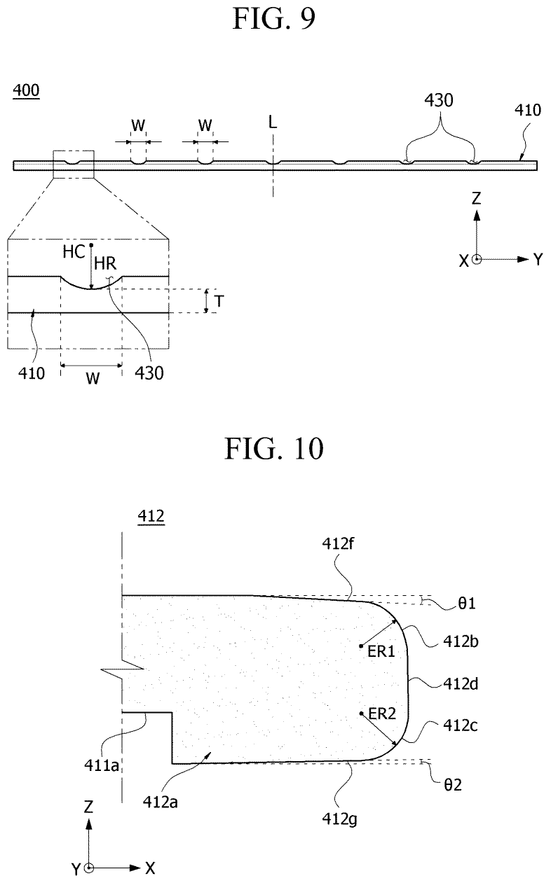

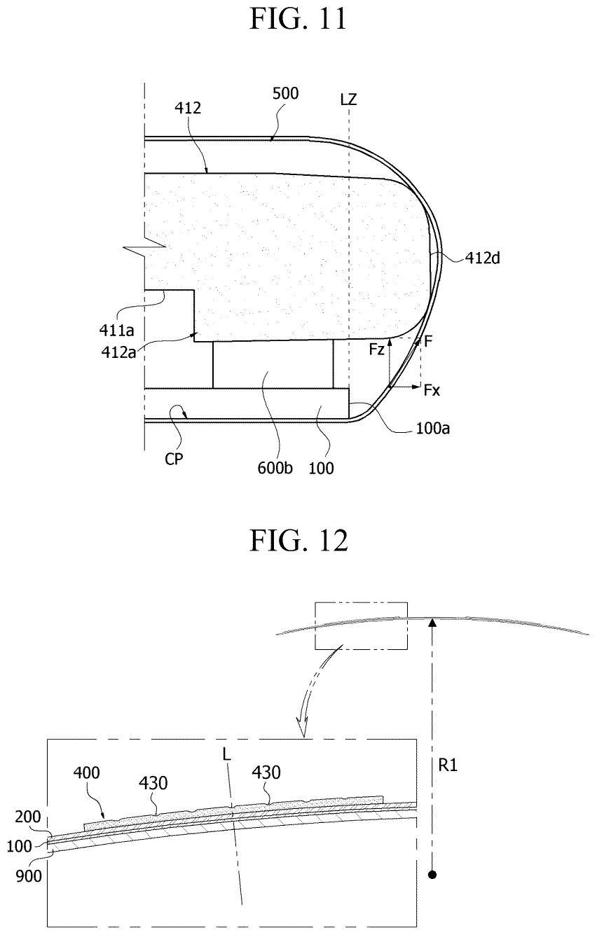

FIG. 7 is a perspective view illustrating the support member 400, as a first example (in other words, first practical example), which is arranged in the display device 1 according to an embodiment of the present disclosure. FIG. 8 is a plan view illustrating the support member 400 of the first example that is arranged in the display device 1 according to the embodiment of the present disclosure. FIG. 9 is a side view illustrating the support member 400 of the first example that is arranged in the display device 1 according to the embodiment of the present disclosure. FIG. 10 is an enlarged view illustrating a support portion of the support member 400 that is arranged in the display device 1 according to the embodiment of the present disclosure. FIG. 11 is a view illustrating an arrangement relationship between the support portion of the support member 400 and the flexible film 500 that are arranged in the display device 1 according to the embodiment of the present disclosure. FIG. 12 is a view schematically illustrating an arrangement relationship among the cover member 900, the display panel 100, the plate 200, and the support member 400, which are formed with a predetermined curvature of the display device 1 according to the embodiment of the present disclosure. The support member 400, which is illustrated in FIGS. 7 to 9, may be hereinafter referred to as the support member according to the first practical example.

With reference to FIGS. 7 to 10, the support member 400 may include a body 410 and a drive chip accommodating portion 420 formed in a back surface of the body 410. In addition, the support member 400 may include a plurality of grooves 430 formed in the back surface of the body 410 in such a manner that the support member 400 may be used in a flat type display device or a curved type display device. In other words, the support member 400 may be used in a flat type display device or a curved type display device by means of the grooves 430 formed therein. Therefore, the support member 400 may be shared by a flat type display device and a curved type display device.

The body 410 may be formed in the shape of a rectangle and may include a body portion 411 and a support portion 412 that extends in a first direction (that is, the X-axis direction) from the body portion 411. In this case, the body portion 411 and the support portion 412 may be integrally formed into one piece.

The body portion 411 may be formed in the shape of a plate. The body portion 411 of the support member 400 may be attached to the back surface of the plate 200 through the adhesive member 10 and may overlap the plate 200 in the Z-axis direction.

The support portion 412 may be formed in such a manner as to have a greater thickness than the body portion 411 and may include a curved surface in order to support the flexible film 500 that is bent. Accordingly, the support portion 412 may include a protrusion 412a that protrudes more toward the display panel 100 than a front surface 411a of the body portion 411, and an end surface that guides bending of the flexible film 500.

In addition, the support portion 412 may be arranged in a manner that protrudes more outward in the X-axis direction (the first direction) than the lateral surface 100a of the display panel 100, taking into consideration a position of the bending section of the flexible film 500 and the stress being applied to the respective jointing portions of the display panel 100 and the flexible film 500. Accordingly, the end surface may also be arranged in a manner that is positioned more outward in the X-axis direction than the lateral surface 100a of the display panel 100.

In addition, a position of the end surface may be adjusted according to a shape of the support portion 412 and to the extent to which the support portion 412 protrudes.

It can be best seen, for example, from FIG. 11, the closer the end surface is to an imaginary line LZ that extends in the Z-axis direction of the lateral surface 100a of the display panel 100, the more likely it is that respective connecting portions CPs of the display panel 100 and the flexible film 500 will be damaged due to a force F applied to the flexible film 500. Accordingly, in the display device 1 according to the embodiment of the present disclosure, the likelihood of the respective connecting portions CPs being damaged due to the force F may be reduced by distributing the force F by application of a shearing stress Fx through the support portion 412.

However, because an objective of the display device 1 according to the embodiment of the present disclosure is to achieve a narrow bezel, there is a limitation on the extent to which the support portion 412 protrudes. Accordingly, the display device 1 according to the embodiment of the present disclosure may be made compact and at the same time, the likelihood of the respective connecting portions CPs may be reduced by bringing respective contact regions of the support portion 412 and the flexible film 500 close to the respective connecting portions CPs using the protrusion 412a.

With reference to FIG. 10, the end surface may include a first end curved surface 412b, a second end curved surface 412c, and an end flat surface 412d arranged between the first end curved surface 412b and the second end curved surface 412c. In addition, the end surface may include a first inclination surface 412f connecting the first end curved surface 412b and a back surface of the body portion 411 to each other, and a second inclination surface 412g extending in the X-axis direction from an end of the second end curved surface 412c.

The protrusion 412a may be arranged closer to the display panel 100 than the front surface 411a of the body portion 411. The second end curved surface 412c and the second inclination surface 412g may be arranged on the protrusion 412a. Accordingly, the second end curved surface 412c may also be arranged closer to the display panel 100 than the front surface 411a of the body portion 411. In this case, the protrusion 412a may be arranged in a manner that is spaced apart from the back surface of the display panel 100, in order to prevent damage caused by contact between the protrusion 412a and the display panel 100.

With reference to FIG. 11, the end surface may make a two-point contact with the flexible film 500 at two points on a vertical cross-section of the end surface using the first end curved surface 412b, the second end curved surface 412c, and the end flat surface 412d arranged between the first end curved surface 412b and the second end curved surface 412c. This two-point contact may prevent or minimize movement of the flexible film 500. In this case, since the flexible film 500 comes into contact with the first end curved surface 412b and the second end curved surface 412c, the end flat surface 412d may be arranged in a manner that is spaced away from the flexible film 500. In this case, the first end curved surface 412b may be a curved surface formed in such a manner as to have a predetermined curvature radius ER1, and the second end curved surface 412c may be a curved surface in such a manner as to have a predetermined curvature radius ER2.

The curvature radius ER1 of the first end curved surface 412b and the curvature radius ER2 of the second end curved surface 412c may be different from each other. Accordingly, the curvature of the first end curved surface 412b and the curvature of the second end curved surface 412c may be different from each other. Specifically, the curvature radius ER2 of the second end curved surface 412c may be smaller than the curvature radius ER1 of the first end curved surface 412b. For example, the curvature radius ER2 of the second end curved surface 412c may be 0.3 mm, and the curvature radius ER1 of the first end curved surface 412b may be 0.4 mm. Accordingly, the second end curved surface 412c is formed in such a manner as to have a gentler curvature than the first end curved surface 412b. Because of this, the second end curved surface 412c increases the extent to which contact with the flexible film 500 is made, and at the same time, increases the magnitude of the shearing stress Fx. These increases may reduce the likelihood of the respective connecting portions CPs being damaged.

The end flat surface 412d is formed as a flat surface and may be arranged in the Z-axis direction.

The first inclination surface 412f may be a flat surface connecting the first end curved surface 412b and the back surface of the body portion 411 to each other, and may be formed in such a manner as to have a predetermined first inclination angle θ1 with respect to the back surface of the body portion 411.

The second inclination surface 412g may be a flat surface that extends in the X-axis direction from the end of the second end curved surface 412c, and may be formed in such a manner as to have a predetermined second inclination angle θ2 with respect to an imaginary flat surface parallel with the back surface of the body portion 411.

Positions of the first end curved surface 412b and the second end curved surface 412c may be set taking into consideration stress applied to the respective contact regions of the support portion 412 and the flexible film 500 and to the respective connecting portions CP of the display panel 100 and the flexible film 500. Because of this, the first inclination angle θ1 and the second inclination angle θ2 may be different from each other. Specifically, the second inclination angle θ2 may be smaller than the first inclination angle θ1. For example, the second inclination angle θ2 may be 1 degree, and the first inclination angle θ1 may be 3 degrees.

Meanwhile, because the body portion 411 is fixed to the plate 200 by the adhesive member 10, the support portion 412 may be formed in a manner that protrudes in the shape of a cantilever. Accordingly, a predetermined load may cause the support member 400 to move. Therefore, in the display device 1 according to the embodiment of the present disclosure, the support portion 412 may be attached to the back surface of the display panel 100 using a second adhesive member 600b.

With reference to FIG. 4, the drive chip accommodating portion 420 may be formed in the back surface of the body 410 of the support member 400 in a manner that corresponds to a drive chip 510, and the drive chip 510 may be arranged within the drive chip accommodating portion 420. In this case, the drive chip 510 may be arranged in such a manner that an air gap is formed between the drive chip accommodating portion 420 and the drive chip 510. Accordingly, the air gap may minimize transfer of heat generated in the drive chip 510 to the support member 400.

The drive chip accommodating portion 420 may be a groove concavely formed in the back surface of the support member 400 or may be a hole passing through the support member 400 in the Z-axis direction. Accordingly, the drive chip accommodating portion 420 may provide a space into which the drive chip 510 may be accommodated. For example, the groove formed in the drive chip accommodating portion 420 may be referred to as a drive chip accommodation groove, and the hole formed in the drive chip accommodating portion 420 may be referred to as a drive chip accommodation hole.

With reference to FIGS. 3 and 4, the drive chip accommodating portion 420 may be concavely formed in the back surface of the support member 400. Here, the groove may be formed to be elongated (in other words, over a relatively long distance) in the Y-axis direction (a second direction) in a manner that corresponds to the drive chip 510. In this case, the drive chip 510 may be arranged in a manner that is spaced apart from the bottom surface and lateral surfaces of the groove that define the groove. Accordingly, the air gap is formed between the drive chip accommodating portion 420 and the drive chip 510, and thus, the air gap may prevent contact between the drive chip 510 and the support member 400. Moreover, since the flexible film 500 may be attached to two first adhesive members 600a, a predetermined tensile force occurs to the flexible film 500 between the two first adhesive members 600a. With this tensile force, the drive chip 510, arranged between the two first adhesive members 600a, is enabled to be more effectively prevented from coming into contact with the support member 400.

In a case where the drive chip accommodating portion 420 is formed as a hole, the drive chip 510 may be arranged by the hole in a manner that faces the plate 200. Accordingly, an increase in the Z-axis direction in the size of the air gap may more effectively prevent the contact of the drive chip 510 with the support member 400.

With reference to FIG. 7, a plurality of grooves 430 may be formed in the body 410 in such a manner as to be spaced apart in the Y-axis direction from each other and may be formed to be elongated (in other words, over a relatively long distance, for example, across the whole width of the body 410) in the X-axis direction.

For example, with reference to FIG. 12, in a case where the display device 1 according to the embodiment of the present disclosure is of a curved type, the arrangement of the plurality of grooves 430 enables effective correspondence to the curvature of the display device 1. For example, when the cover member 900 of the curved-type display device includes a curved surface formed to have a predetermined curvature radius R1, the display panel 100 and the plate 200 may also be arranged in a manner that corresponds to a curved surface of the cover member 900. Accordingly, the support member 400 may be bent in such a manner as to have a predetermined curvature. Therefore, in the display device 1 according to the embodiment of the present disclosure, the plurality of grooves 430 are formed in the support member 400 in such a manner as to be arranged to be spaced apart from each other in the Y-axis direction, while extending in an elongated form in the X-axis direction. This formation enables the support member 400 to be readily bent to have a predetermined curvature. The groove 430 here may be referred to as a bending groove.

For example, since the support member 400 extends in an elongated form in the X-direction rather than in the Y-axis direction, a large number of the grooves 430 may be formed in the back surface of the body 410 in such a manner as to be spaced apart from each other along the Y-axis direction. The plurality of grooves 430 that are arranged in such a manner as to be spaced apart from each other along the Y-axis direction enables the support member 400, shaped to have a predetermined curvature, to be readily formed.

For example, with reference to FIG. 8, the plurality of grooves 430 may be formed in the back surface of the body 410 in such a manner as to be spaced the same distance D apart from each other. In this case, one of the plurality of grooves 430 may be formed along an imaginary line L that passes through the center C of the support member 400 in the X-axis direction. The plurality of grooves 430 may be formed in such a manner as to be symmetrical with respect to the imaginary line L. Accordingly, the support member 400 may be bent at a predetermined curvature with respect to the groove 430 formed along the imaginary line L. Here, the groove 430, formed along the imaginary line L, may be referred to as the central groove.

In addition, for example, with respect to FIG. 9, the groove 430 may be formed in such a manner as to have an arc-shaped cross-section with a predetermined curvature radius HR from an imaginary center HC. Accordingly, the groove 430 may be concavely formed in the back surface of the body 410 in such a manner as to have a predetermined depth. Therefore, the plurality of grooves 430 having the same width W are arranged in the support member 400 of the first example, in such a manner as to be spaced a predetermined distance D apart from each other, with the support member 400 having the same thickness T at the groove 430. Thus, the support member 400 may be bent at a predetermined curvature in a manner that corresponds to a curved surface of the plate 200.

At least one flexible film 500 may electrically connect the display panel 100 and the substrate 300 to each other. Specifically, the flexible film 500 may connect pad electrodes of the display panel 100 to output terminals of the substrate 300. In this case, the flexible film 500 may be bonded to the display panel 100 through the anisotropic conductive film (ACF). The flexible film 500 here may be a flexible printed circuit board (FPCB) or a chip on film (COF) on which an IC, which results from integrating circuits of a data driver (DD) and/or a gate driver (GD), is mounted, but is not limited to the FPCB and the COF. The flexible film 500 may be referred to as a flexible circuit film, and the IC may be referred to a drive chip 510.

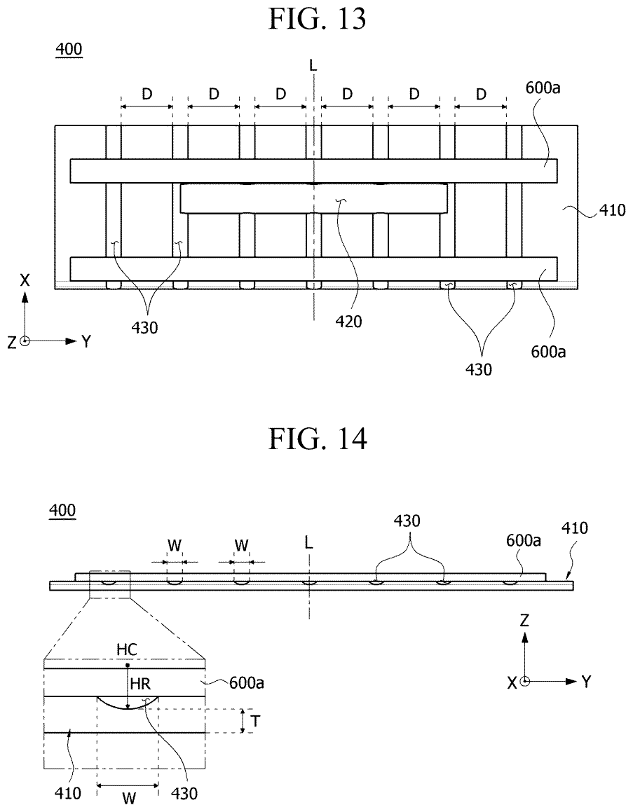

FIG. 13 is a plan view illustrating an arrangement relationship between the support member 400 and the first adhesive member 600a of the display device 1 according to the embodiment of the present disclosure. FIG. 14 is a side view illustrating the arrangement relationship between the support member 400 and the first adhesive member 600a of the display device 1 according to the embodiment of the present disclosure.

The first adhesive member 600a may attach one region of the flexible film 500 to the back surface of the support member 400.

With reference to FIGS. 2, 13, and 14, the first adhesive member 600a may be arranged to be elongated (in other words, over a relatively long distance, for example, across a large part of the support member 400) in the Y-axis direction on the back surface of the support member 400. The first adhesive member 600a here may be made from a material with adhesiveness, such as a form tape.

For example, two first adhesive members 600a may be arranged in such a manner as to be spaced apart from each other in the X-axis direction. Accordingly, because the flexible film 500 is attached to the two first adhesive members 600a, one region of the flexible film 500 arranged between the two first adhesive members 600a may support a load using a tensile force. With reference to FIGS. 3 and 4, because the drive chip 510 is attached to one region of the flexible film 500 arranged between the two first adhesive members 600a, the drive chip 510 is affected by the tensile force. Therefore, the contact between the drive chip 510 and the support member 400 may be prevented by the tensile force.

With reference to FIG. 4, the arrangement of the second adhesive member 600b between the display panel 100 and the support member 400 may attach the support portion 412 of the support member 400 to an edge of a back surface of the display panel 100. Accordingly, the second adhesive member 600b may prevent the movement of the support portion 412. The second adhesive member 600b here may be made from a material with adhesiveness, such as a form tape, and may overlap the support portion 412 in the Z-axis direction.

The optical member 700 may be arranged on the front surface of the display panel 100. In this case, the optical member 700 may be attached to the front surface of the display panel 100 using the adhesive member 10. In this case, the adhesive member 10 arranged between the optical member 700 and the display panel 100 may be formed of a transparent material with excellent adhesiveness, for example, optically clear adhesive (OCA), pressure-sensitive adhesive (PSA), or optically cleared resin (OCR), but is not limited to these materials.

In addition, the optical member 700 may include an optical angle adjustment structure in order to adjust a range of visibility of an image displayed on the display panel 100. In addition, the optical member 700 may also include a polarizer controlling display properties (for example, external light reflection, color accuracy, luminance, and the like). In addition, the optical member 700 may further include a barrier layer (or a barrier film) for preventing penetration of moisture or oxygen, and the barrier layer may be formed of a material with low water vapor permeability, for example, a polymer material.

In addition, the optical member 700 may have a smaller area than the display panel 100, taking into consideration one portion of the flexible film 500 that is arranged on a front surface edge of the display panel 100. Accordingly, as illustrated in FIG. 4, a predetermined space S may be formed between an edge of the display panel 100 and the cover adhesive member 800 or between the edge of the display panel 100 and the cover member 900.

The cover adhesive member 800 is arranged on the front surface of the optical member 700 and may attach the cover member 900. The cover adhesive member 800 here may be formed of a transparent material with excellent adhesiveness, for example, optically clear adhesive (OCA), pressure-sensitive adhesive (PSA), or optically cleared resin (OCR), but is not limited to these materials.

In addition, the cover adhesive member 800 may be formed in a manner that has a larger area than the optical member 700 and has the same area as the display panel 100. Accordingly, the predetermined space S may be formed between the edge of the display panel 100 and the cover adhesive member 800.

In addition, the cover adhesive member 800 may also be formed in a manner that has the same area as the optical member 700. Accordingly, the predetermined space S may also be formed between the edge of the display panel 100 and the cover member 900.

The cover member 900 is arranged on the front surface of the display panel 100 and may protect the display panel 100. In this case, the cover member 900 may be attached to the front surface of the display panel 100 using an adhesive member, such as the cover adhesive member 800.

In addition, the cover member 900 may be formed in a manner that has a larger horizontal area than the display panel 100 and the cover adhesive member 800. Accordingly, even though the display panel 100 is attached to a back surface of the cover member 900, an edge of the back surface of the cover member 900 may be exposed, and an end of the housing may be arranged on the exposed edge.

In addition, the cover member 900 may include a light-blocking layer arranged on the edge, such as a black matrix. The light-blocking layer enables components arranged in the non-display area NA to be shielded from exposure to the outside. For example, the light-blocking layer may be arranged on a back surface edge of the cover member 900 in such a manner that respective portions of the flexible film 500 and the like, arranged in a manner that overlaps the non-display area NA, is invisible from the outside.

In addition, the cover member 900 may be formed of a transparent material. Accordingly, light emitted from the display panel 100 may pass through the cover member 900.

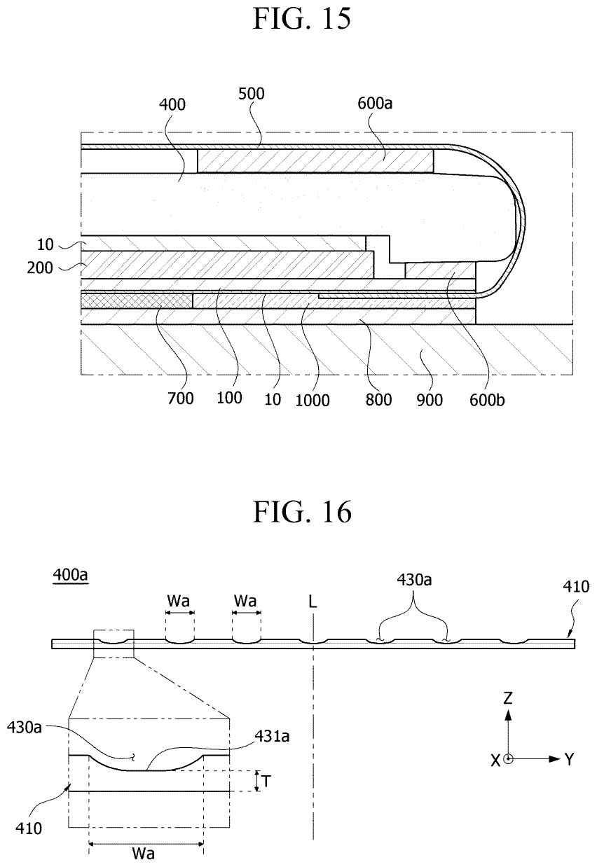

FIG. 15 is a view illustrating a filling member 1000 of the display device 1 according to the embodiment of the present disclosure.

The filling member 1000 may be arranged between the display panel 100 and the cover adhesive member 800 when viewed in the Z-axis direction. With reference to FIGS. 4 and 15, the filling member 1000 may be arranged in the predetermined space S formed between the edge of the display panel 100 and the cover adhesive member 800.

The filling member 1000 may be inserted into the predetermined space S, and thus the space S may be occupied by (filled with) the filling member 1000. Accordingly, the filling member 1000 may prevent the cover adhesive member 800 from being separated from the optical member 700, by absorbing impact applied to the cover member 900. For example, in a case where the filling member 1000 is not provided, when a predetermined impact is applied to the cover member 900, a phenomenon where the cover member 900 peels off may occur, or the cover adhesive member 800 may be separated from the optical member 700. Accordingly, the filling member 1000 may absorb impact.

Therefore, by absorbing impact, the filling member 1000 may prevent the flexible film 500 from being separated from the display panel 100.

In addition, the filling member 1000 may be formed of acrylic or epoxy-based resin, which has an excellent visible light transmittance, for example, a visible light transmittance of 90% or higher, but it is not limited to these materials.

In addition, the filling member 1000 is arranged in such a manner as to cover one portion of the flexible film 500 arranged on the front surface edge of the display panel 100, and thus may securely fix the flexible film 500 in place. Accordingly, the filling member 1000 may reduce the likelihood of the respective connecting portions CP of the display panel 100 and the flexible film 500 being damaged. The filling member 1000 here may be a material that, like resin, is inserted and then cured. For this reason, the filling member 1000 may be referred to as an adhesive member.

In addition, depending on the horizontal area of the cover adhesive member 800, the filling member 1000 may also be arranged between the display panel 100 and the cover member 900 when viewed in the Z-axis direction.

Support members described below may also correspond to various curvatures of the curved-type display as well as the flat-type display device.

The curved-type display device may be manufactured in such a manner as to have various curvatures. The more the curvature of the curved surface of the cover member 900 increases, the more the curvature of the support member 400 increases. Therefore, the display device according to the embodiment of the present disclosure may provide various practical examples of the support member 400 that may accommodate the curvature, double-curvature curved surface, or the like of the curved-type display device.

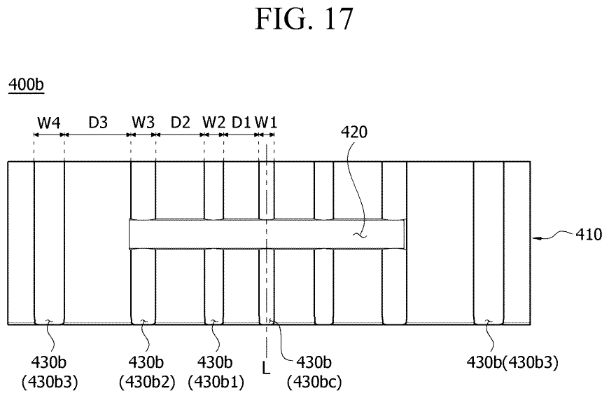

FIG. 16 is a view illustrating grooves in a support member 400a, as a second example (in other words, second practical example), which is arranged on the display device 1 according to the embodiment of the present disclosure. Here, the support member illustrated in FIG. 16 may be referred to as the support member 400a of the second example. The support member 400a of the second example, may be used in place of the support member of the first example.

With reference to FIGS. 9 and 16, the support member 400a of the second example, is different from the support member 400 of the first example, in that a groove 430a in the support member 400a has a greater width Wa than the groove 430 in the support member 400.

Components of the support member 400a of the second example, may have the same reference numerals as those of the support member 400 of the first example. Therefore, a detailed description of the components, having the same reference numerals, of the support member 400a, is omitted when describing the support member 400a of the second example.

With reference to FIG. 16, the groove 430a may be formed in the support member 400a in such a manner as to have a U-shaped cross-section or to have a cross-section similar to a dish with a bottom.

For example, the groove 430a includes a bottom surface 431a arranged between two curved surfaces having a predetermined curvature. Because of this, the support member 400a of the second example, may have an increased width Wa of the groove 430a. The bottom surface 431a here may be a flat surface. Accordingly, the support member 400a may have an increased width Wa through the bottom surface 431a of the groove 430a. Thus, although the curvature of the cover member 900 increases due to the bending of the cover member 900, the support member 400a may readily accommodate the curvature of the cover member 900.

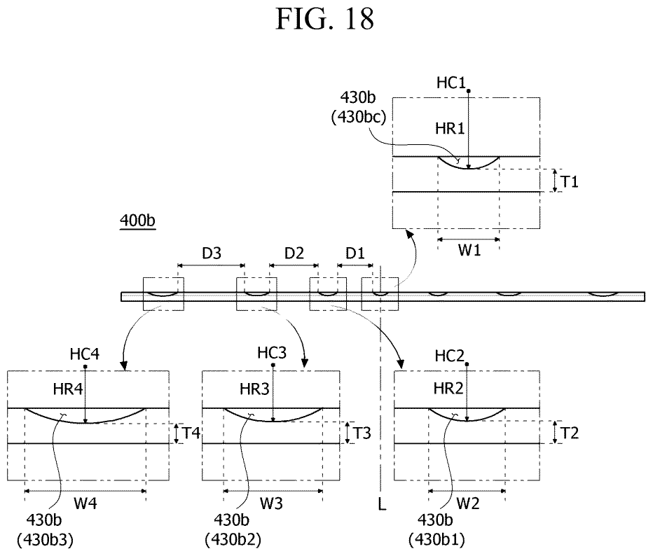

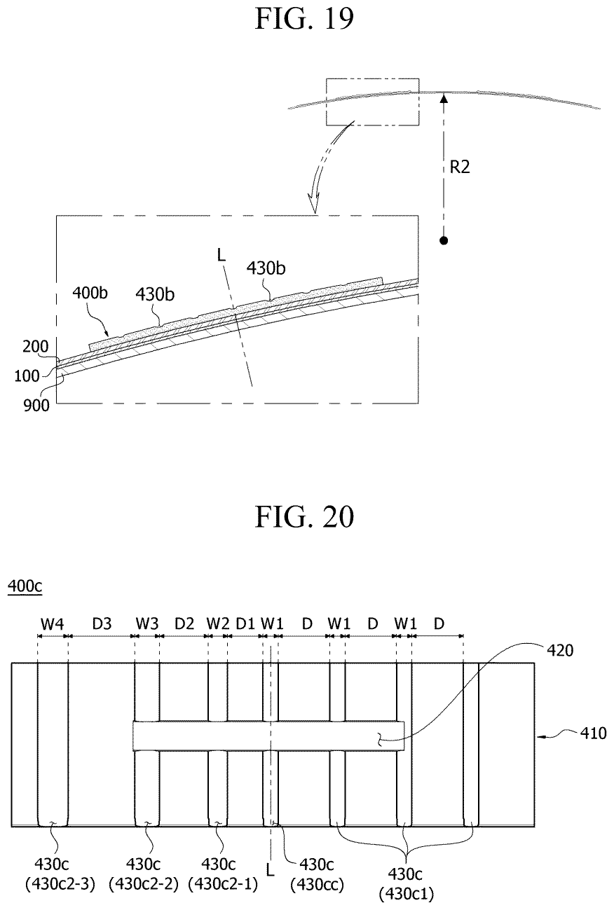

FIG. 17 is a plan view illustrating a support member 400b, as a third example (in other words, third practical example), of the display device 1 according to the embodiment of the present disclosure. FIG. 18 is a side view illustrating the support member 400b of the third example, of the display device 1 according to the embodiment of the present disclosure. FIG. 19 is a view illustrating an arrangement relationship among the cover member 900, the display panel 100, and the plate 200, and the support member 400b of the third example, which are formed with a predetermined curvature of the display device 1 according to the embodiment of the present disclosure. The support member 400b of the third example, may be used in place of the support member 400 of the first example.

With reference to FIGS. 9, 12, 17, 18, and 19, the support member 400b of the third example, is different from the support member 400 of the first example, in that a distance between grooves 430b in the support member 400b is different from a distance between the grooves 430 in the support member 400. In addition, the support member 400b is different from the support member 400 in that a curvature radius R2 of the cover member 900 on which the support member 400b of the third example, is arranged is smaller than the curvature radius R1 of the cover member 900 on which the support member 400 of the first example, is arranged.

Components of the support member 400b of the third example, may have the same reference numerals as those of the support member 400 of the first example. Therefore, a detailed description of the components, having the same reference numerals, of the support member 400b, is omitted when describing the support member 400b of the third example.

With reference to FIGS. 17 and 18, the support member 400b may include the body 410, the drive chip accommodating portion 420 formed in the back surface of the body 410, and a plurality of grooves 430b that are formed in the back surface of the body 410. In this case, the plurality of grooves 430b may be formed in a manner that is symmetrical with respect to the imaginary line L. The imaginary line L here may be a line that passes through the center C of the support member 400b in the X-axis direction.

The plurality of grooves 430b may include a central groove 430bc, which is formed along the imaginary line L, a first groove 430b1, a second groove 430b2, and a third groove 430b3, which are formed in such a manner as to be sequentially spaced a predetermined distance apart from the central groove 430bc along the Y-axis direction. In this case, a total of 7 grooves 430b are formed in the support member 400b of the third example, but the support member 400b is not necessarily limited to the total of 7 grooves 430b. For example, 8 or more grooves 430b, or 6 or less grooves 430b may be formed in the support member 400b. However, an odd number of grooves 430b may be formed in the back surface of the body 410, taking into consideration the fact that the central groove 430bc is formed in the center of the support member 400b and the fact that a plurality of grooves 430b are formed in a manner that is symmetrical with respect to the imaginary line L.

As a practical example, the farther a respective one of a plurality of grooves 430b is positioned from the imaginary line L, the greater a distance between the respective one and an adjacent one of the plurality of grooves 430b becomes.

In addition, the farther a respective one of the plurality of grooves 430b is positioned from the imaginary line L, the greater a curvature radius of the respective one of the plurality of grooves 430b becomes. Accordingly, the farther a respective one of the plurality of grooves 430b is positioned from the imaginary line L, the greater the width of the respective one of the plurality of grooves 430b becomes. Because of this, although the curvature of the cover member 900 increases due to the bending of the cover member 900, the support member 400b may readily accommodate the curvature of the cover member 900. In this case, the center of each of the plurality of grooves 430b may be positioned on an imaginary horizontal plane, but is not necessarily limited to this plane. Here, the horizontal plane on which the center of each of the plurality of grooves 430b is positioned may be in parallel with a back surface of the support member 400b.

In addition, the farther a respective one of the plurality of grooves 430b is positioned from the imaginary line L, the greater the depth of the respective one of the plurality of grooves 430b becomes. Accordingly, the farther a respective one of the plurality of grooves 430b is positioned from the imaginary line L, the greater the width of the respective one of the plurality of grooves 430b becomes. The farther a respective one of the plurality of grooves 430b are positioned from the imaginary line L, the smaller the thickness of the support member 400b at the respective one of the plurality of 430b becomes.

The central groove 430bc may be formed along the imaginary line L.

The central groove 430bc may be formed in such a manner as to have an arc-shaped cross-section with a predetermined first curvature radius HR1 from an imaginary first center HC1. Accordingly, the central groove 430bc may be concavely formed in the back surface of the body 410 in such a manner as to have a predetermined depth. The support member 400b may be formed in such a manner as to have a first thickness T1 at the central groove 430bc. The central groove 430bc may be formed in such a manner as to have a first width W1 in the Y-axis direction. In this case, the first thickness T1 and the first width W1 may be adjusted by a position of the first center HC1. For example, the first curvature radius HR1 may be 1.4 mm, and the first thickness T1 may be 0.4 mm.

The first groove 430b1 may be formed in a manner that is spaced apart from the imaginary line L in the Y-axis direction. Accordingly, the first groove 430b1 may be formed in a manner that is spaced a first distance D1 apart from the central groove 430bc. The first distance D1 here may be a separation distance between the central groove 430bc and the first groove 430b1 or may be a distance from the center of the central groove 430bc to the center of the first groove 430b1. The first distance D1 may be 7.0 mm.

The first groove 430b1 may be formed in such a manner as to have an arc-shaped cross-section with a predetermined second curvature radius HR2 from an imaginary second center HC2. In this case, the second curvature radius HR2 of the first groove 430b1 may be greater than the first curvature radius HR1 of the central groove 430bc. For example, the second curvature radius HR2 of the first groove 430b1 may be 2.0 mm. The first center HC1 and the second center HC2 may be positioned on an imaginary horizontal plane parallel with the back surface of the support member 400b.

The first groove 430b1 may be concavely formed in the back surface of the body 410 in such a manner as to have a predetermined depth. The support member 400b may be formed in such a manner as to have a second thickness T2 at the first groove 430b1. The first groove 430b1 may be formed in such a manner as to have a second width W2 in the Y-axis direction. For example, the second thickness T2 may be 0.38 mm.

The second groove 430b2 may be formed in a manner that is positioned farther in the Y-axis direction from the imaginary line L than the first groove 430b1. Accordingly, the second groove 430b2 may be formed in a manner that is spaced a second distance D2 apart from the first groove 430b1. The second distance D2 here may be a separation distance between the first groove 430b1 and the second groove 430b2 or may be a distance from the center of the first groove 430b1 to the center of the second groove 430b2. For example, the second distance D2 may be 9.0 mm.

The second groove 430b2 may be formed in such a manner as to have an arc-shaped cross-section with a predetermined third curvature radius HR3 from the imaginary third center HC3. In this case, the third curvature radius HR3 of the second groove 430b2 may be greater than the second curvature radius HR2 of the first groove 430b1. For example, the third curvature radius HR3 of the second groove 430b2 may be 3.0 mm. The first center HC1, the second center HC2, and the third center HC3 may be positioned on an imaginary horizontal plane parallel with the back surface of the support member 400b.

The second groove 430b2 may be concavely formed in the back surface of the body 410 in such a manner as to have a predetermined depth. The support member 400b may be formed in such a manner as to have a third thickness T3 at the second groove 430b2. The second groove 430b2 may be formed in such a manner as to have a third width W3 in the Y-axis direction. For example, the third width W3 may be 0.35 mm.

The third groove 430b3 may be formed in a manner that is positioned farther in the Y-axis direction from the imaginary line L than the second groove 430b2. Accordingly, the third groove 430b3 may be formed in a manner that is spaced a third distance D3 apart from the second groove 430b2. The third distance D3 here may be a separation distance between the second groove 430b2 and the third groove 430b3 or may be a distance from the center of the second groove 430b2 to the center of the third groove 430b3. For example, the third distance D3 may be 12.0 mm.

The third groove 430b3 may be formed in such a manner as to have an arc-shaped cross-section with a predetermined fourth curvature radius HR4 from the imaginary fourth center HC4. In this case, the fourth curvature radius HR4 of the third groove 430b3 may be greater than the third curvature radius HR3 of the second groove 430b2. For example, the fourth curvature radius HR4 of the third groove 430b3 may be 4.0 mm. The first center HC1, the second center HC2, the third center HC3, and the fourth center HC4 may be positioned on an imaginary horizontal plane parallel with the back surface of the support member 400b.

The third groove 430b3 may be concavely formed in the back surface of the body 410 in such a manner as to have a predetermined depth. The support member 400b may be formed in such a manner as to have a fourth thickness T4 at the third groove 430b3. The third groove 430b3 may be formed in such a manner as to have a fourth width W4 in the Y-axis direction. For example, the fourth width W4 may be 0.3 mm.

Accordingly, when the curved-type display device has the cover member 900 bent to a large extent, such as a case where the curvature radius R2 of the cover member 900 of the third example on which the support member 400b is arranged is smaller than the curvature radius R1 of the cover member 900 of the first example on which the support member 400 is arranged, the display device according to the embodiment of the present disclosure may accommodate the curved-type display device having the large extent of bending by adjusting the distance between adjacent ones of the plurality of grooves 430b.

In addition, the display device according to the embodiment of the present disclosure may more easily accommodate the curved-type display device having the large extent of bending by adjusting the curvature radius of each of the plurality of grooves 430b so as to adjust the depth and width of each of the plurality of grooves 430b.

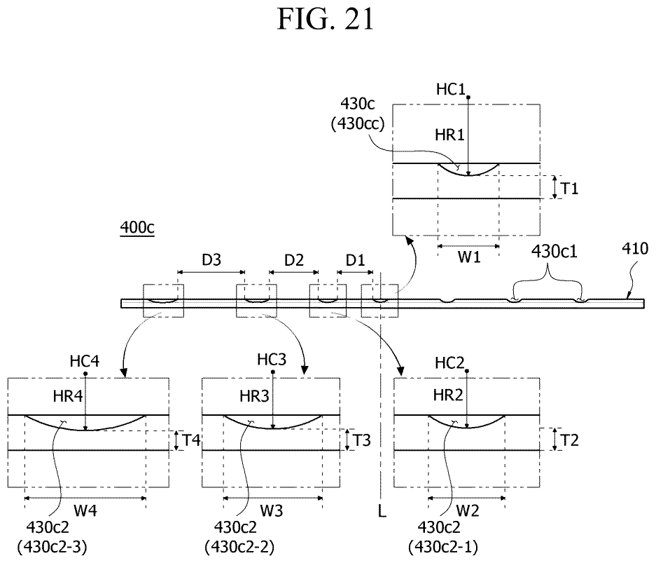

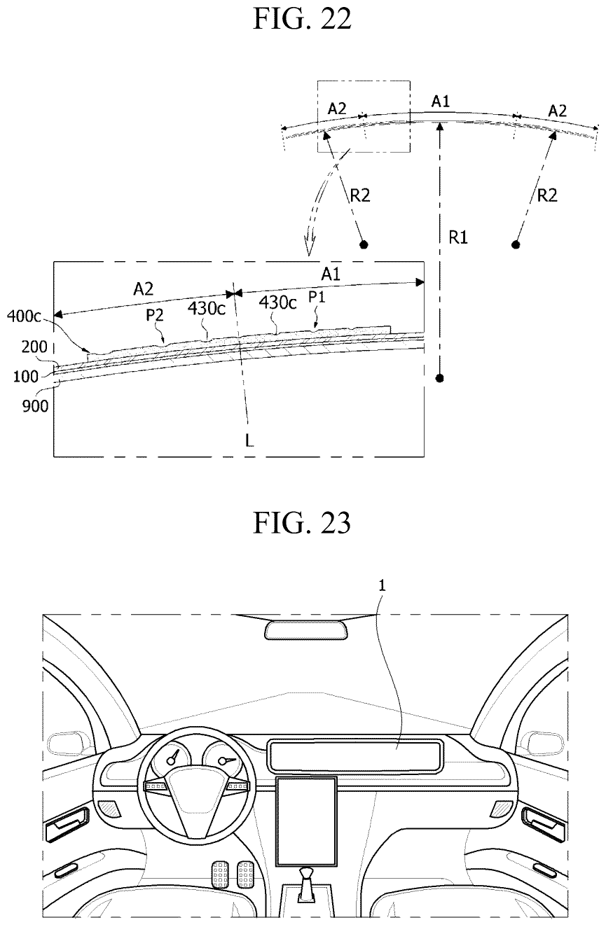

FIG. 20 is a plan view illustrating a support member 400c, as a fourth practical example, of the display device 1 according to the embodiment of the present disclosure. FIG. 21 is a side view illustrating the support member 400c of the fourth example, of the display device 1 according to the embodiment of the present disclosure. FIG. 22 is a view illustrating an arrangement relationship among the cover member 900, the display panel 100, the plate 100, and the support member 400c of the fourth example, which are formed with a predetermined curvature of the display device 1 according to the embodiment of the present disclosure. The support member 400c of the fourth example, may be used in place of the support member 400 of the first example.

With reference to FIGS. 9, 12, 20, 21, and 22, the support member 400c of the fourth example, is different from the support member 400 of the first example, in that the support member 400c includes parts in which distances between adjacent ones of the plurality of grooves 430 are different from each other. In addition, the cover member 900 on which the support member 400c of the fourth example, is arranged is formed in such a manner as to have at least two curvature radii, that is, a first curvature radius R1 and a second curvature radius R2. In this respect, the cover member 900 on which the support member 400c of the fourth example, is arranged is different from the cover member 900 on which the support member 400 of the first example, is arranged. For example, in addition to a first region A1 formed at a first curvature radius R1, the cover member 900 on which the support member 400c of the fourth example, is arranged includes a second region A2 formed at a second curvature radius R2. The first curvature radius R1 and the second curvature radius R2 are different from each other. In this respect, the cover member 900 on which the support member 400c is arranged is different from the cover member 900 on which the support member 400 is arranged. The first curvature radius R1 here may be greater than the second curvature radius R2. The first curvature radius R1 here may represent a distance from the imaginary center to a curved surface of the cover member 900 arranged in the first region A1. The second curvature radius R2 here may represent a distance from the imaginary center to the curved surface of the cover member 900 arranged in the second region A2.

Components of the support member 400c of the fourth example, may have the same reference numerals as those of the support member 400 of the first example and the same as those of the support member 400b of the third example. Therefore, a detailed description of the components, having the same reference numerals, of the support member 400c is omitted when describing the support member 400c of the fourth example.

With reference to FIGS. 20, 21 and 22, the support member 400c may include a first part P1 corresponding to the first region A1 and a second part P2 corresponding to the second region A2. In this case, the first part P1 and the second part P2 may be distinguished by the imaginary line L that passes through the center C of the support member 400c in the X-axis direction. In this case, the support member 400c may be arranged on the back surface of the plate 200 in such a manner that the imaginary line L overlaps a border line that distinguishes between the first region A1 and the second region A2. For example, the imaginary L, when extending in the Z-axis direction, may meet the border line.

The support member 400c may include the body 410, the drive chip accommodating portion 420 formed in the back surface of the body 410, and a plurality of grooves 430c that are formed in the back surface of the body 410. In this case, the plurality of grooves 430c may be formed in a manner that is asymmetrical with respect to the imaginary line L.

The plurality of grooves 430c may include a central groove 430cc formed along the imaginary line L, a first part groove 430c1 formed in the first part P1, and a second part groove 430c2 formed in the second part P2.

The central groove 430cc may be formed along the imaginary line L.

The central groove 430cc may be formed in such a manner as to have an arc-shaped cross-section with the predetermined first curvature radius HR1 from the imaginary first center HC1. Accordingly, the central groove 430cc may be concavely formed in the back surface of the body 410 in such a manner as to have a predetermined depth. The support member 400c may be formed in such a manner as to have the first thickness T1 at the central groove 430cc. The central groove 430cc may be formed in such a manner as to have the first width W1 in the Y-axis direction. In this case, the first thickness T1 and the first width W1 may be adjusted by the position of the first center HC1. For example, the first curvature radius HR1 of the central groove 430cc may be 1.4 mm, and the first thickness T1 thereof may be 0.4 mm.

A plurality of first part grooves 430c1 may be formed in a region, corresponding to the first part P1, of the back surface of the body 410 in such a manner as to be spaced the same distance D apart from each other. The first part groove 430c1 may be formed in the same shape as the central groove 430cc.

The first part groove 430c1 may be formed in such a manner as to have an arc-shaped cross-section with the predetermined first curvature radius HR1 from the imaginary first center HC1. Accordingly, the first part groove 430c1 may be concavely formed in the back surface of the body 410 in such a manner as to have a predetermined depth.

Accordingly, a plurality of first part grooves 430c1 having the same first width W1 are formed in the support member 400c of the fourth example, with the support member 400c having the same thickness T1 at the first part groove 430c1. Thus, the support member 400c may accommodate the first curvature radius R1 of the cover member 900.

The second part groove 430c2 may include a (2-1)-nd groove 430c2-1, a (2-2)-nd groove 430c2-2, and a (2-3)-nd groove 430c2-3 that are formed in such a manner as to be sequentially spaced apart from the central groove 430cc along the Y-axis direction. In this case, the second part groove 430c2 includes a total of three grooves, but is not necessarily limited to the three grooves. For example, the second part groove 430c2 may also include four or more grooves or may also include two or less grooves.

In addition, the farther a respective one of a plurality of second part grooves 430c2 is positioned from the imaginary line L, the greater a separation distance between the respective one and an adjacent one of the plurality of second part grooves 430c2 becomes.

In addition, the farther a respective one of the plurality of second part grooves 430c2 is positioned from the imaginary line L, the greater a curvature radius of the respective one of the plurality of second part grooves 430c2 becomes. In this case, the center of each of the plurality of second part grooves 430c2 may be positioned on an imaginary horizontal plane, but is not necessarily limited to this plane. Here, the horizontal plane on which the center of each of the plurality of second part grooves 430c2 is positioned may be in parallel with the back surface of the support member 400b.

In addition, the farther a respective one of the plurality of second part grooves 430c2 is positioned from the imaginary line L, the greater the depth of the respective one of the plurality of second part grooves 430c2 becomes. Accordingly, the farther a respective one of the plurality of second part grooves 430c2 is positioned from the imaginary line L, the greater the width of the respective one of the plurality of second part grooves 430c2 becomes. The farther a respective one of the plurality of second part grooves 430c2 is positioned from the imaginary line L, the smaller the thickness of the support member 400b at the respective one of the plurality of second part grooves 430c2 becomes.

The (2-1)-nd groove 430c2-1 may be formed in a manner that is spaced apart from the imaginary line L in the Y-axis direction. Accordingly, the (2-1)-nd groove 430c2-1 may be formed in a manner that is spaced the first distance D1 apart from the central groove 430cc. The first distance D1 here may be a separation distance between the central groove 430cc and the (2-1)-nd groove 430c2-1 or may be a distance from the center of the central groove 430cc to the center of the (2-1)-nd groove 430c2-1. For example, the first distance D1 may be 7.0 mm.

The (2-1)-nd groove 430c2-1 may be formed in such a manner as to have an arc-shaped cross-section with the predetermined second curvature radius HR2 from the imaginary second center HC2. In this case, the second curvature radius HR2 of the (2-1)-nd groove 430c2-1 may be greater than the first curvature radius HR1 of the central groove 430cc. For example, the second curvature radius HR2 of the (2-1)-nd groove 430c2-1 may be 2.0 mm. The first center HC1 and the second center HC2 may be positioned on an imaginary horizontal plane parallel with the back surface of the support member 400c.

The (2-1)-nd groove 430c2-1 may be concavely formed in the back surface of the body 410 in such a manner as to have a predetermined depth. The support member 400c may be formed in such a manner as to have the second thickness T2 at the (2-1)-nd groove 430c2-1. The (2-1)-nd groove 430c2-1 may be formed in such a manner as to have the second width W2 in the Y-axis direction. For example, the second thickness T2 may be 0.38 mm.

The (2-2)-nd groove 430c2-2 may be formed in a manner that is positioned farther in the Y-axis direction from the imaginary line L than the (2-1)-nd groove 430c2-1. Accordingly, the (2-2)-nd groove 430c2-2 may be formed in a manner that is spaced the second distance D2 apart from the (2-1)-nd groove 430c2-1. The second distance D2 here may be a separation distance between the (2-1)-nd groove 430c2-1 and the (2-2)-nd groove 430c2-2 or may be a distance from the center of the (2-1)-nd groove 430c2-1 to the center of the (2-2)-nd groove 430c2-2. For example, the second distance D2 may be 9.0 mm.

The (2-2)-nd groove 430c2-2 may be formed in such a manner as to have an arc-shaped cross-section with the predetermined third curvature radius HR3 from the third imaginary center HC3. In this case, the third curvature radius HR3 of the (2-2)-nd groove 430c2-2 may be greater than the second curvature radius HR2 of the (2-1)-nd groove 430c2-1. For example, the third curvature radius HR3 of the (2-2)-nd groove 430c2-2 may be 3.0 mm. The first center HC1, the second center HC2, and the third center HC3 may be positioned on an imaginary horizontal plane parallel with a back surface of the support member 400c.

The (2-2)-nd groove 430c2-2 may be concavely formed in the back surface of the body 410 in such a manner as to have a predetermined depth. The support member 400c may be formed in such a manner as to have the third thickness T3 at the (2-2)-nd groove 430c2-2. The (2-2)-nd groove 430c2-2 may be formed in such a manner as to have the third width W3 in the Y-axis direction. For example, the third width W3 may be 0.35 mm.

The (2-3)-nd groove 430c2-3 may be formed in a manner that is positioned farther in the Y-axis direction from the imaginary line L than the (2-2)-nd groove 430c2-2. Accordingly, the (2-3)-nd groove 430c2-3 may be formed in a manner that is spaced the third distance D3 apart from the (2-2)-nd groove 430c2-2. The third distance D3 here may be a separation distance between the (2-2)-nd groove 430c2-2 and the (2-3)-nd groove 430c2-3 or may be a distance from the center of the (2-2)-nd groove 430c2-2 to the center of the (2-3)-nd groove 430c2-3. For example, the third distance D3 may be 12.0 mm.

The (2-3)-nd groove 430c2-3 may be formed in such a manner as to have an arc-shaped cross-section with the predetermined fourth curvature radius HR4 from the imaginary fourth center HC4. In this case, the fourth curvature radius HR4 of the (2-3)-nd groove 430c2-3 may be greater than the third curvature radius HR3 of the (2-2)-nd groove 430c2-2. For example, the fourth curvature radius HR4 of the (2-3)-nd groove 430c2-3 may be 4.0 mm. The first center HC1, the second center HC2, the third center HC3, and the fourth center HC4 may be positioned on an imaginary horizontal plane parallel with the back surface of the support member 400b.

The (2-3)-nd groove 430c2-3 may be concavely formed in the back surface of the body 410 in such a manner as to have a predetermined depth. The support member 400c may be formed in such a manner as to have the fourth thickness T4 at the (2-3)-nd groove 430c2-3. The (2-3)-nd groove 430c2-3 may be formed in such a manner as to have the fourth width W4 in the Y-axis direction. For example, the fourth width W4 may be 0.3 mm.

The cover member 900 may include a curved surface having at least two different curvatures.

With reference to FIG. 22, the cover member 900 include the first region A1 formed with the first curvature radius R1 and the second region A2 formed with the second curvature radius R2. In this case, since the first curvature radius R1 and the second curvature radius R2 are different from each other, one surface of the cover member 900 may include a curved surface having at least two curvatures.

The second regions A2 may be positioned in the Y-axis direction on both sides, respectively, of the first region A1. Accordingly, an imaginary border line may be positioned between the first region A1 and the second region A2 that have different curvatures. The first curvature radius R1 here may be greater than the second curvature radius R2. Accordingly, a curved surface may be more gently bent in the first region A1 than in the second region A2.

In addition, the border line may be positioned in a manner that overlaps the imaginary line L that passes through the support member 400c. Accordingly, although the first region A1 and the second region A2 have different curvatures, parts of the support member 400c may readily accommodate the curvatures, respectively, of the first region A1 and the second region A2. Therefore, the first region A1 may overlap the first part P1 of the support member 400c, and the second region A2 may overlap the second part P2 of the support member 400c.

Since a distance between the grooves 430c varies from one part to another in the support member 400c of the fourth example, the support member 400c may accommodate at least two curvature radii of the cover member 900. In addition, the second part groove 430c2 formed in the second part P2 varies in width and depth according to a position of the second part groove 430c2 in the support member 400c of the fourth example. Thus, the support member 400c may more readily accommodate at least two curvature radii of the cover member 900.

Therefore, the display device according to the embodiment of the present disclosure may accommodate the curved-type display device including at least two curved surfaces having different curvatures by using the support member 400c of the fourth example.

FIG. 23 is a view illustrating an example where the display device 1 according to the embodiment of the present disclosure is used, that is, an example where the display device 1 is arranged within a vehicle.

As illustrated in FIG. 23, the display device 1 according to the embodiment of the present disclosure may be arranged on at least one portion of a dashboard of the vehicle. In this case, the dashboard of the vehicle may represent one of components of the vehicle, which are arranged in front of a front seat (for example, a driver's seat or a passenger's seat) in the vehicle. Inputting components for performing functions of various systems (for example, an air conditioning system, an audio system, and a navigation system), which are provided in the vehicle, may be arranged on the dashboard of the vehicle.

The display device 1 may be arranged on the dashboard of the vehicle and may operate as an input device for performing at least one of various functions of the vehicle. In addition, the display device 1 may provide various pieces of information, associated with the vehicle, for example, driving information of the vehicle (for example, current speed of the vehicle, a fuel gauge reading, and a fuel range) and component information of the vehicle (for example, the extent of damage to a tire of the vehicle).

In addition, the display device 1 may be arranged to span the space between the driver's seat and the passenger's seat that are installed in the front of the vehicle. Users of the display device 1 may include a driver sitting on the driver's seat and an occupant sitting on the passenger's seat, but are not necessarily limited to them. For example, the display device 1 may be arranged for an occupant sitting on a rear seat in the vehicle.

In an embodiment, the display device 1 as illustrated in FIG. 23 is shown only in part. The display device 1 as illustrated in FIG. 23 may represent a display panel among various components that may be included in the display device 1. Among the components of the display device 1, components other than those illustrated in FIG. 23 may be mounted within the vehicle.

The display device mounted on a vehicle is an example for describing the present disclosure, and an embodiment herein is not limited thereto.

The display device according to an embodiment of the present disclosure may be applicable to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an e-book, a portable multimedia player (PMP), a personal digital assistant (PDA), an MP3 player, a mobile medical device, a desktop PC, a laptop PC, a netbook computer, a workstation, a navigation device, an in-vehicle navigation device, an in-vehicle display apparatus, an in-vehicle device, theater device, theater display apparatus, a television, a wallpaper device, a signage device, a gaming device, a laptop, a monitor, a camera, a camcorder, and a home appliance. Further, the display device of the present disclosure may be applicable to an organic light-emitting lighting device or an inorganic light-emitting lighting device.

The embodiments of the present disclosure described above are briefly described as follows.

A display device according to the embodiments of the present disclosure may include: a display panel; a plate arranged on a back surface of the display panel; a substrate and a support member, both arranged on a back surface of the plate; and a flexible film connecting the display panel and the substrate to each other, wherein the flexible film may be attached to a back surface of the support member by a first adhesive member.

In the display device according to the embodiments of the present disclosure, the support member may include a body portion and a support portion extending in a first direction from the body portion, the flexible film may come into contact with an end surface of the support portion, and the support portion may protrude more outward than a lateral surface of the display panel in the first direction.

In the display device according to the embodiments of the present disclosure, the support portion may have a greater thickness than the body portion.

In the display device according to the embodiments of the present disclosure, the end surface may include a first end curved surface, a second end curved surface, and an end flat surface arranged between the first end curved surface and the second end curved surface, the first end curved surface and the second end curved surface may come into contact with the flexible film, and the end flat surface may be spaced apart from the flexible film.

In the display device according to the embodiments of the present disclosure, the curvature of the first end curved surface and the curvature of the second end curved surface may be different from each other.

In the display device according to the embodiments of the present disclosure, the end surface may further include a first inclination surface connecting the first end curved surface and a back surface of the body portion to each other, and a second inclination surface extending in the first direction from an end of the second end curved surface.

In the display device according to the embodiments of the present disclosure, the support portion may include a protrusion that protrudes more toward the display panel than a front surface of the body portion, the second end curved surface and the second inclination surface may be arranged on the protrusion, the second end curved surface may be closer to the display panel than the front surface of the body portion, and the protrusion may be spaced apart from the back surface of the display panel.

In the display device according to the embodiments of the present disclosure, the first inclination surface may have a first inclination angle with respect to the back surface of the body portion, the second inclination surface may have a second inclination angle with respect to an imaginary flat surface parallel with the back surface of the body portion, and the first inclination angle and the second inclination angle may be different from each other.

In the display device according to the embodiments of the present disclosure, the support portion may be attached to the back surface of the display panel by a second adhesive member.

In the display device according to the embodiments of the present disclosure, the number of the first adhesive member may be two, and two first adhesive members may be arranged in such a manner as to be spaced apart from each other in a first direction, and a drive chip mounted on the flexible film may be arranged between the two first adhesive members.

In the display device according to the embodiments of the present disclosure, the support member may include a drive chip accommodating portion corresponding to the drive chip, and the drive chip accommodating portion may be a groove concavely formed in the back surface of the support member or a hole passing through the support member.

In the display device according to the embodiments of the present disclosure, an end of the drive chip may be spaced apart from the support member.

In the display device according to the embodiments of the present disclosure, the drive chip may be arranged within the drive chip accommodating portion, and an air gap may be formed between the drive chip accommodating portion and the drive chip.

In the display device according to the embodiments of the present disclosure, the support member may include a plurality of grooves that are formed in such a manner as to be spaced apart from each other in a second direction, and the plurality of grooves may be formed to be elongated in a first direction that is different from the second direction.

In the display device according to the embodiments of the present disclosure, the plurality of grooves may be formed to be spaced the same distance apart from each other.

In the display device according to the embodiments of the present disclosure, the plurality of grooves may have the same width and the support member may have the same thickness at the plurality of grooves.

In the display device according to the embodiments of the present disclosure, each of the plurality of grooves may have an arc-shaped cross-section with a predetermined curvature.

In the display device according to the embodiments of the present disclosure, each of the plurality of grooves may have a U-shaped cross-section or a cross-section similar to a dish with a bottom.

In the display device according to the embodiments of the present disclosure, one of the plurality of grooves may be formed along an imaginary line that passes through the center of the support member in the first direction.

In the display device according to the embodiments of the present disclosure, the farther a respective one of the plurality of grooves is positioned from the imaginary line, the greater the distance between the respective one and an adjacent one of the plurality of grooves may be.

In the display device according to the embodiments of the present disclosure, the farther a respective one of the plurality of grooves is positioned from the imaginary line, the greater the depth of the respective one of the plurality of grooves may be.

In the display device according to the embodiments of the present disclosure, each of the plurality of grooves may have an arc-shaped cross-section with a predetermined curvature, and the farther a respective one of the plurality of grooves is positioned from the imaginary line, the greater a curvature radius of the respective one of the plurality of grooves may be.

In the display device according to the embodiments of the present disclosure, the plurality of grooves may be formed in such a manner as to be symmetrical with respect to the imaginary line L.

In the display device according to the embodiments of the present disclosure, the plurality of grooves may be formed in such a manner as to be asymmetrical with respect to the imaginary line.

The display device according to the embodiments of the present disclosure may further include: an optical member arranged on a front surface of the display panel and having a smaller area than the display panel; a cover adhesive member arranged on a front surface of the optical member and having a larger area than the optical member; and a cover member arranged on a front surface of the cover adhesive member, wherein the cover member may include a first region and a second region that have different curvature radii.

In the display device according to the embodiments of the present disclosure, the support member may include a body including a first part corresponding to the first region and a second part corresponding to the second region, and a plurality of grooves formed in a back surface of the body in such a manner as to be spaced apart from each other in a second direction, wherein the plurality of grooves may be formed in the first part in such a manner as to be spaced the same distance apart from each other, and the plurality of grooves may be formed in the second part in such a manner as to be spaced different distances apart from each other.

The display device according to the embodiments of the present disclosure may further include: an optical member arranged on a front surface of the display panel and having a smaller area than the display panel; a cover adhesive member arranged on a front surface of the optical member and having a larger area than the optical member; a cover member arranged on a front surface of the cover adhesive member; and a filling member arranged between the display panel and the cover adhesive member, wherein the filling member may cover one portion of the flexible film.

The display device according to the embodiments of the present disclosure, a predetermined space may be formed between an edge of the display panel and the cover adhesive member or between an edge of the display panel and the cover member, and the filling member may be arranged in the predetermined space.

A display device according to the embodiments of the present disclosure may include: a display panel; a plate arranged on a back surface of the display panel; a substrate and a support member, both arranged on a back surface of the plate; a flexible film connecting the display panel and the substrate to each other; and a cover member arranged to the front surface side of the display panel, wherein the flexible film may be attached to a back surface of the support member by a first adhesive member, wherein the cover member may include a curved surface with a predetermined curvature, and the support member may include a plurality of grooves that are formed to be elongated in a first direction in such a manner as to be spaced apart from each other in a second direction that is different from the first direction.

In the display device according to the embodiments of the present disclosure, one of the plurality of grooves may be formed along an imaginary line that passes through the center of the support member in the first direction, and the farther a respective one of the plurality of grooves is positioned from the imaginary line, the greater a distance between the respective one and an adjacent one of the plurality of grooves may be.

In the display device according to the embodiments of the present disclosure, the cover member may include a first region and a second region that have different curvature radii, the support member may include a first part corresponding to the first region and a second part corresponding to the second region, the plurality of grooves may be formed in a back surface of the support member in such a manner as to be spaced apart from each other, the plurality of grooves may be formed in the first part in such a manner as to be spaced the same distance apart from each other, and the plurality of grooves may be formed in the second part in such a manner as to be spaced different distances apart from each other.

The objects to be achieved by the present disclosure, the means for achieving the objects, and effects of the present disclosure described above do not specify essential features of the claims, and thus, the scope of the claims is not limited to the disclosure of the present disclosure.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

[Description of Reference Numerals]

| | |
|---|---|
| 100: Display panel | 200: Plate |
| 300: Substrate | 400: Support member |
| 410: Body | |
| 420: Driving chip accommodating portion | |
| 430, 430a, 430b, 430c: Groove | |
| 500: Flexible film | 600a: First adhesive member |
| 700: Optical member | 800: Cover adhesive member |
| 900: Cover member | 1000: Filling member |

What is claimed is:

1. A display device, comprising:
a display panel;
a plate arranged on a back surface of the display panel;
a substrate and a support member, both arranged on a back surface of the plate; and
a flexible film connecting the display panel and the substrate to each other,
wherein the flexible film is attached to a back surface of the support member by a first adhesive member.

2. The display device of claim 1, wherein the support member includes a body portion and a support portion extending in a first direction from the body portion,
wherein the flexible film comes into contact with an end surface of the support portion, and
wherein the support portion protrudes more outward than a lateral surface of the display panel in the first direction.

3. The display device of claim 2, wherein the support portion has a greater thickness than the body portion.

4. The display device of claim 2, wherein the end surface includes a first end curved surface, a second end curved surface, and an end flat surface arranged between the first end curved surface and the second end curved surface,
wherein the first end curved surface and the second end curved surface come into contact with the flexible film, and
wherein the end flat surface is spaced apart from the flexible film.

5. The display device of claim 4, wherein the curvature of the first end curved surface and the curvature of the second end curved surface are different from each other.

6. The display device of claim 4, wherein the end surface further includes a first inclination surface connecting the first end curved surface and a back surface of the body portion to each other, and a second inclination surface extending in the first direction from an end of the second end curved surface.

7. The display device of claim 6, wherein the support portion includes a protrusion that protrudes more toward the display panel than a front surface of the body portion, the second end curved surface and the second inclination surface are arranged on the protrusion, the second end curved surface is closer to the display panel than the front surface of the body portion, and the protrusion is spaced apart from the back surface of the display panel.

8. The display device of claim 7, wherein the first inclination surface has a first inclination angle with respect to the back surface of the body portion, the second inclination surface has a second inclination angle with respect to an imaginary flat surface parallel with the back surface of the body portion, and the first inclination angle and the second inclination angle are different from each other.

9. The display device of claim 2, wherein the support portion is attached to the back surface of the display panel by a second adhesive member.

10. The display device of claim 1, wherein the number of the first adhesive member is two, and two first adhesive members are arranged in such a manner as to be spaced apart from each other in a first direction, and
wherein a drive chip mounted on the flexible film is arranged between the two first adhesive members.

11. The display device of claim 10, wherein the support member includes a drive chip accommodating portion corresponding to the drive chip, and
wherein the drive chip accommodating portion is a groove concavely formed in the back surface of the support member or a hole passing through the support member.

12. The display device of claim 10, wherein an end of the drive chip is spaced apart from the support member.

13. The display device of claim 11, wherein the drive chip is arranged within the drive chip accommodating portion, and an air gap is formed between the drive chip accommodating portion and the drive chip.

14. The display device of claim 10, wherein the support member includes a plurality of grooves that are formed in such a manner as to be spaced apart from each other in a second direction, and
wherein the plurality of grooves are formed to be elongated in a first direction that is different from the second direction.

15. The display device of claim 1, wherein the support member includes a plurality of grooves that are formed in such a manner as to be spaced apart from each other in a second direction, and
wherein the plurality of grooves are formed to be elongated in a first direction that is different from the second direction.

16. The display device of claim 15, wherein the plurality of grooves are formed to be spaced the same distance apart from each other.

17. The display device of claim 15, wherein the plurality of grooves have the same width and the support member has the same thickness at the plurality of grooves.

18. The display device of claim 15, wherein each of the plurality of grooves has an arc-shaped cross-section with a predetermined curvature.

19. The display device of claim 15, wherein each of the plurality of grooves has a U-shaped cross-section or a cross-section similar to a dish with a bottom.

20. The display device of claim 15, wherein one of the plurality of grooves is formed along an imaginary line that passes through the center of the support member in the first direction.

21. The display device of claim 20, wherein the farther a respective one of the plurality of grooves is positioned from the imaginary line, the greater the distance between the respective one and an adjacent one of the plurality of grooves becomes.

22. The display device of claim 20, wherein the farther a respective one of the plurality of grooves is positioned from the imaginary line, the greater the depth of the respective one of the plurality of grooves becomes.

23. The display device of claim 20, wherein each of the plurality of grooves has an arc-shaped cross-section with a predetermined curvature, and
wherein the farther a respective one of the plurality of grooves is positioned from the imaginary line, the greater a curvature radius of the respective one of the plurality of grooves becomes.

24. The display device of claim 20, wherein the plurality of grooves are formed in such a manner as to be symmetrical with respect to the imaginary line.

25. The display device of claim 20, wherein the plurality of grooves are formed in such a manner as to be asymmetrical with respect to the imaginary line.

26. The display device of claim 1, further comprising:
an optical member arranged on a front surface of the display panel and having a smaller area than the display panel;
a cover adhesive member arranged on a front surface of the optical member and having a larger area than the optical member; and
a cover member arranged on a front surface of the cover adhesive member,
wherein the cover member includes a first region and a second region that have different curvature radii.

27. The display device of claim 26, wherein the support member includes a body including a first part corresponding to the first region and a second part corresponding to the second region, and a plurality of grooves formed in a back surface of the body in such a manner as to be spaced apart from each other in a second direction,
wherein the plurality of grooves are formed in the first part in such a manner as to be spaced the same distance apart from each other, and
wherein the plurality of grooves are formed in the second part in such a manner as to be spaced different distances apart from each other.

28. The display device of claim 1, further comprising:
an optical member arranged on a front surface of the display panel and having a smaller area than the display panel;
a cover adhesive member arranged on a front surface of the optical member and having a larger area than the optical member;
a cover member arranged on a front surface of the cover adhesive member; and
a filling member arranged between the display panel and the cover adhesive member,
wherein the filling member covers one portion of the flexible film.

29. The display device of claim 28, wherein a predetermined space is formed between an edge of the display panel and the cover adhesive member or between an edge of the display panel and the cover member, and the filling member is arranged in the predetermined space.

30. A display device, comprising:
a display panel;
a plate arranged on a back surface of the display panel;
a substrate and a support member, both arranged on a back surface of the plate;
a flexible film connecting the display panel and the substrate to each other; and
a cover member arranged on a front surface side of the display panel,
wherein the flexible film is attached to a back surface of the support member by a first adhesive member,
wherein the cover member includes a curved surface with a predetermined curvature, and
wherein the support member includes a plurality of grooves that are formed to be elongated in a first direction in such a manner as to be spaced apart from each other in a second direction that is different from the first direction.

31. The display device of claim 30, wherein one of the plurality of grooves is formed along an imaginary line that passes through the center of the support member in the first direction, and
wherein the farther a respective one of the plurality of grooves is positioned from the imaginary line, the greater a distance between the respective one and an adjacent one of the plurality of grooves becomes.

32. The display device of claim 30, wherein the cover member includes a first region and a second region that have different curvature radii,
wherein the support member includes a first part corresponding to the first region and a second part corresponding to the second region,
wherein the plurality of grooves are formed in a back surface of the support member in such a manner as to be spaced apart from each other,
wherein the plurality of grooves are formed in the first part in such a manner as to be spaced the same distance apart from each other, and
wherein the plurality of grooves are formed in the second part in such a manner as to be spaced different distances apart from each other.
